(19) United States
(12) Patent Application Publication
(10) Pub. No.: US 2023/0290921 A1
(43) Pub. Date: Sep. 14, 2023

(54) PIXEL AND DISPLAY DEVICE INCLUDING THE SAME

(71) Applicant: Samsung Display Co., LTD., Yongin-si (KR)

(72) Inventors: Dong Hee SHIN, Yongin-si (KR); Sun Kwun SON, Yongin-si (KR); Na Hyeon CHA, Yongin-si (KR)

(21) Appl. No.: 18/183,819

(22) Filed: Mar. 14, 2023

(30) Foreign Application Priority Data
Mar. 14, 2022 (KR) 10-2022-0031396

(51) Int. Cl. H01L 33/62; H01L 25/16; H01L 27/12

(52) U.S. Cl. CPC H01L 33/62; H01L 25/167; H01L 27/124

(57) ABSTRACT

A pixel according to one or more embodiments of the disclosure may comprise a first sub-pixel, a second sub-pixel, and a third sub-pixel arranged in a first direction, and including an emission area, a non-emission area, a first alignment electrode extending in the first direction, a second alignment electrode extending in the first direction, and spaced apart from the first alignment electrode in a second direction crossing the first direction, a light-emitting element between the first alignment electrode and the second alignment electrode, and including a first end and a second end opposite each other with respect to the second direction, and a first electrode and a second electrode electrically connected to the light-emitting element, and spaced apart from each other in the second direction, the first electrode overlapping the first end of the light-emitting element, and the second electrode overlapping the second end of the light-emitting element.

### CROSS-REFERENCE TO RELATED APPLICATION

This application claims priority to, and the benefit of, Korean Patent Application No. 10-2022-0031396, filed on, Mar. 14, 2022, the content of which in its entirety is herein incorporated by reference.

### BACKGROUND

### 1. Field

The disclosure relates to a pixel and a display device including the same.

### 2. Description of the Related Art

Recently, as interest in information display is increased, research and development of a display device are continuously being conducted.

### SUMMARY

An aspect of the disclosure provides a pixel with improved reliability, and a display device including the same.

A pixel according to one or more embodiments of the disclosure may include a first sub-pixel, a second sub-pixel, and a third sub-pixel arranged in a first direction, and including an emission area, a non-emission area, a first alignment electrode extending in the first direction, a second alignment electrode extending in the first direction, and spaced apart from the first alignment electrode in a second direction crossing the first direction, a light-emitting element between the first alignment electrode and the second alignment electrode, and including a first end and a second end opposite each other with respect to the second direction, and a first electrode and a second electrode electrically connected to the light-emitting element, and spaced apart from each other in the second direction, the first electrode overlapping the first end of the light-emitting element, and the second electrode overlapping the second end of the light-emitting element.

The first electrode of each of the first, second, and third sub-pixels may be spaced apart from the first electrode of one of the sub-pixels adjacent in the first direction, wherein the second electrode of each of the first, second, and third sub-pixels is connected to the second electrode of the one of the sub-pixels adjacent in the first direction.

The second electrode of the first sub-pixel, the second electrode of the second sub-pixel, and the second electrode of the third sub-pixel may be integrally provided.

The pixel may further include a first bank in the non-emission area, and defining a first opening corresponding to the emission area, and a second opening spaced apart from the first opening, a first connection line extending in the second direction in the non-emission area of the first sub-pixel, and connected to the first alignment electrode, and a second connection line extending in the second direction in the non-emission area of the third sub-pixel, and connected to the second alignment electrode.

The first alignment electrode of the first sub-pixel, the first alignment electrode of the second sub-pixel, and the first alignment electrode of the third sub-pixel may be connected to each other, wherein the second alignment electrode of the first sub-pixel, the second alignment electrode of the second sub-pixel, and the second alignment electrode of the third sub-pixel are connected to each other.

The pixel may further include a first bridge pattern in the non-emission area of the first sub-pixel, and electrically connected to the second electrode of the first sub-pixel, a second bridge pattern in the non-emission area of the second sub-pixel, and electrically connected to the second electrode of the second sub-pixel, and a third bridge pattern in the non-emission area of the third sub-pixel, and electrically connected to the second electrode of the third sub-pixel, wherein the first bridge pattern, the second bridge pattern, and the third bridge pattern are spaced apart from each other.

The third bridge pattern and the second connection line may be integrally provided.

The first alignment electrode, the second alignment electrode, the first bridge pattern, the second bridge pattern, the third bridge pattern, the first connection line, and the second connection line may be in a same layer, and may include a same material.

The pixel may further include a substrate, a storage capacitor above the substrate, and electrically connected to the first end of the light-emitting element, a transistor above the substrate, and electrically connected to the storage capacitor, a data line above the substrate, configured to be electrically connected to the transistor, configured to receive a data signal, and extending in a direction perpendicular to an extension direction of the first and second alignment electrodes, a first power line above the substrate, configured to be electrically connected to the transistor, and configured to receive a voltage of first driving power, a second power line above the substrate, configured to be electrically connected to the second end of the light-emitting element, and configured to receive a voltage of second driving power, and a passivation layer above the transistor, the first power line, and the second power line, and exposing a portion of the storage capacitor, a portion of the first power line, and a portion of the second power line.

The second power line exposed in the first sub-pixel may be electrically connected to the first bridge pattern, wherein the second power line exposed in the second sub-pixel is electrically connected to the second bridge pattern, and wherein the second power line exposed in the third sub-pixel is electrically connected to the third bridge pattern.

The first alignment electrode may include a (1-1)-th alignment electrode, a (1-2)-th alignment electrode, a (1-3)-th alignment electrode, a (1-4)-th alignment electrode, and (1-5)-th alignment electrode extending in the first direction, and spaced apart in the second direction, wherein the second alignment electrode includes a (2-1)-th alignment electrode, a (2-2)-th alignment electrode, a (2-3)-th alignment electrode, a (2-4)-th alignment electrode, and a (2-5)-th alignment electrode extending in the first direction, and spaced apart in the second direction, and wherein the first alignment electrode and the second alignment electrode are alternately located along the second direction.

The first electrode may overlap the (2-1)-th alignment electrode, wherein the second electrode overlaps the (1-5)-th alignment electrode.

The pixel may further include a first intermediate electrode between the first electrode and the second electrode, spaced apart from the first and second electrodes in the second direction, and overlapping the (1-1)-th alignment electrode and the (2-2)-th alignment electrode, a second intermediate electrode between the first intermediate electrode and the second electrode, spaced apart from the first intermediate electrode and the second electrode in the second direction, and overlapping the (1-2)-th alignment electrode and the (2-3)-th alignment electrode, a third intermediate electrode between the second intermediate electrode and the second electrode, spaced apart from the second intermediate electrode and the second electrode in the second direction, and overlapping the (1-3)-th first alignment electrode and the (2-4)-th second alignment electrode, and a fourth intermediate electrode between the third intermediate electrode and the second electrode, spaced apart from the third intermediate electrode and the second electrode in the second direction, and overlapping the (1-4)-th alignment electrode and the (2-5)-th alignment electrode.

In the emission area, the first electrode, the first intermediate electrode, the second intermediate electrode, the third intermediate electrode, the fourth intermediate electrode, and the second electrode may be sequentially arranged along the second direction based on the first electrode of a corresponding sub-pixel.

The first electrode, the second intermediate electrode, and the fourth intermediate electrode may be in a same layer, and may include a same material, wherein the second electrode, the first intermediate electrode, and the third intermediate electrode are in a same layer, and include a same material.

The first electrode, the first intermediate electrode, the second intermediate electrode, the third intermediate electrode, the fourth intermediate electrode, and the second electrode may be in a same layer, and may include a same material.

The pixel may further include a first light-emitting element between the (2-1)-th alignment electrode and the (1-1)-th alignment electrode, and including a first end electrically connected to the first electrode, and a second end electrically connected to the first intermediate electrode, a second light-emitting element between the (2-2)-th alignment electrode and the (1-2)-th alignment electrode, and including a first end electrically connected to the first intermediate electrode, and a second end electrically connected to the second intermediate electrode, a third light-emitting element between the (2-3)-th alignment electrode and the (1-3)-th alignment electrode, and including a first end electrically connected to the second intermediate electrode, and a second end electrically connected to the third intermediate electrode, a fourth light-emitting element between the (2-4)-th alignment electrode and the (1-4)-th alignment electrode, and including a first end electrically connected to the third intermediate electrode, and a second end electrically connected to the fourth intermediate electrode, and a fifth light-emitting element between the (2-5)-th alignment electrode and the (1-5)-th alignment electrode, and including a first end electrically connected to the fourth intermediate electrode, and a second end electrically connected to the second electrode.

The first to fifth light-emitting elements may include a first semiconductor layer, an active layer, and a second semiconductor layer, wherein the first semiconductor layer includes an n-type semiconductor layer doped with an n-type dopant, wherein the second semiconductor layer includes a p-type semiconductor layer doped with a p-type dopant, wherein the second semiconductor layer of the first to fifth light-emitting elements is at the first end of a corresponding light-emitting element, and wherein the first semiconductor layer of the first to fifth light-emitting elements is at the second end of the corresponding light-emitting element.

The pixel may further include a second bank above the first bank in the non-emission area, a color conversion layer above the first to fifth light-emitting elements in the emission area, and configured to convert light of a first color emitted from the first to fifth light-emitting elements into light of a second color, and a color filter above the color conversion layer, and configured to selectively transmit the light of the second color.

A display device according to one or more embodiments of the disclosure may include a substrate including a display area and a non-display area, and one or more pixels in the display area, including an emission area and a non-emission area, and including first, second, and third sub-pixels arranged along a first direction, wherein the first, second, and third sub-pixels include a pixel circuit layer above the substrate, and including at least one transistor, and a display element layer above the pixel circuit layer, and including a first alignment electrode extending in the first direction, a second alignment electrode extending in the first direction, and spaced apart from the first alignment electrode in a second direction crossing the first direction, a light-emitting element between the first alignment electrode and the second alignment electrode, including a first end and a second end opposite each other with respect to the second direction, and configured to be electrically connected to the transistor, and a first electrode and a second electrode electrically connected to the light-emitting element, and spaced apart from each other in the second direction, the first electrode overlapping, and electrically connected to, the first end of the light-emitting element, and the second electrode overlapping, and electrically connected to, the second end of the light-emitting element.

The pixel according to an embodiment of the disclosure may include the first and second alignment electrodes (or first and second alignment lines) extending in a horizontal direction (or the first direction), and the light emitting elements may be aligned between the first alignment electrode and the second alignment electrode in a vertical direction (or the second direction) crossing the horizontal direction. Therefore, even though a pixel electrode is displaced from a preset position (or even though a variation occurs in an overlay of the pixel electrode) during a process of forming the pixel electrode (or electrode), a contact defect between the light emitting element and the pixel electrode may be prevented by sufficiently securing a contact area between the light emitting element and the pixel electrode.

Accordingly, reliability of the display device including the above-described pixel may be improved.

An aspect according to one or more embodiments of the disclosure is not limited to the contents illustrated above, and more various aspect are included in the present specification.

### BRIEF DESCRIPTION OF THE DRAWINGS

The above and other aspects of the disclosure will become more apparent by describing in further detail embodiments thereof with reference to the accompanying drawings, in which:

FIG. 1 is a perspective view schematically illustrating a light-emitting element according to one or more embodiments;

FIG. 2 is a schematic cross-sectional view of the light-emitting element of FIG. 1;

FIG. 3 is a plan view schematically illustrating a display device according to one or more embodiments;

FIG. 4 is a schematic circuit diagram illustrating an electrical connection relationship between components included in each of first to third sub-pixels shown in FIG. 3 according to one or more embodiments;

FIG. 5 is a plan view schematically illustrating a pixel circuit layer of a pixel shown in FIG. 3;

FIG. 6 is a schematic cross-sectional view taken along the line I˜I′ of FIG. 5;

FIG. 7 is a plan view schematically illustrating a pixel area including a display element layer of the pixel PXL shown in FIG. 3;

FIG. 8 is a plan view schematically illustrating first and second alignment electrodes and light-emitting elements included in the pixel of FIG. 7;

FIG. 9 is a schematic plan view illustrating a flow of a driving current flowing through a light-emitting unit of the pixel shown in FIG. 7;

FIGS. 10 to 12 are schematic cross-sectional views taken along the line II˜II′ of FIG. 7;

FIG. 13 is a schematic cross-sectional view taken along the line III˜III′ of FIG. 7;

FIG. 14A is a plan view schematically illustrating a first mask forming a first electrode, a second intermediate electrode, and a fourth intermediate electrode in a pixel according to one or more embodiments;

FIG. 14B is a plan view schematically illustrating a second mask forming a first intermediate electrode, a third intermediate electrode, and a second electrode in a pixel according to one or more embodiments;

FIG. 15 is a plan view schematically illustrating a pixel area including an optical layer of the pixel shown in FIG. 3; and

FIGS. 16 to 18 are schematic cross-sectional views taken along the line IV˜IV′ of FIG. 15.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in various different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure. Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the particular illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form in order to avoid unnecessarily obscuring various embodiments.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “plan view,” means viewing a target portion from the top, and the phrase “on a cross-section” means viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

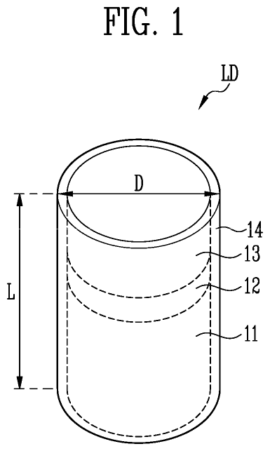

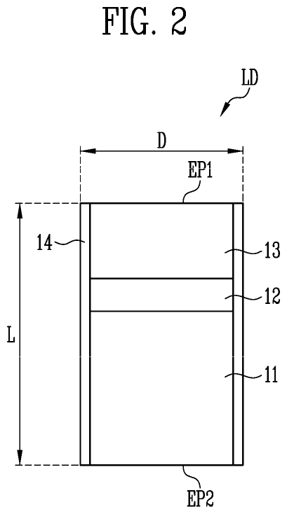

FIG. 1 is a perspective view schematically illustrating a light-emitting element LD according to one or more embodiments, and FIG. 2 is a schematic cross-sectional view of the light-emitting element LD of FIG. 1.

Referring to FIGS. 1 and 2, in one or more embodiments, a type and/or a shape of the light-emitting element LD are/is not limited to the embodiments corresponding to FIGS. 1 and 2.

Referring to FIGS. 1 and 2, the light-emitting element LD may include a first semiconductor layer 11, a second semiconductor layer 13, and an active layer 12 interposed between the first semiconductor layer 11 and the second semiconductor layer 13. For example, the light-emitting element LD may be implemented in a light-emitting stack (or a stack pattern) in which the first semiconductor layer 11, the active layer 12, and the second semiconductor layer 13 are sequentially stacked.

The light-emitting element LD may be provided in a shape extending in one direction. When an extension direction of the light-emitting element LD is referred to as a length direction, the light-emitting element LD may include a first end EP1 and a second end EP2 facing each other along the length direction. One semiconductor layer of the first semiconductor layer 11 and the second semiconductor layer 13 may be positioned at the first end EP1 of the light-emitting element LD, and the other semiconductor layer of the first semiconductor layer 11 and the second semiconductor layer 13 may be positioned at the second end EP2 of the light-emitting element LD. For example, the second semiconductor layer 13 may be positioned at the first end EP1 of the light-emitting element LD, and the first semiconductor layer 11 may be located at the second end EP2 of the light-emitting element LD.

The light-emitting element LD may be provided in various shapes. For example, as shown in FIG. 1, the light-emitting element LD may have a rod-like shape, a bar-like shape, or a column shape that is long in the length direction (or having an aspect ratio greater than 1). As another example, the light-emitting element LD may have a rod-like shape, a bar-like shape, or a column shape that is short in the length direction (or having an aspect ratio of less than 1). As still another example, the light-emitting element LD may have a rod-like shape, a bar-like shape, or a column shape having an aspect ratio of 1.

The light-emitting element LD may include, for example, a light-emitting diode (LED) manufactured to be extremely small to have a diameter D and/or a length L of about a nano scale (or nano meter) to a micro scale (or micro meter).

When the light-emitting element LD is long in the length direction (that is, the aspect ratio is greater than 1), the diameter D of the light-emitting element LD may be about 0.5 μm to about 6 μm, and the length L of the light-emitting element LD may be about 1 μm to about 10 μm. However, the diameter D and the length L of the light-emitting element LD are not limited thereto. A size of the light-emitting element LD may be changed to satisfy a requirement condition (or a design condition) of a lighting device or a self-emission display device to which the light-emitting element LD is applied.

The first semiconductor layer 11 may include, for example, at least one n-type semiconductor layer. For example, the first semiconductor layer 11 may include any one semiconductor material among InAlGaN, GaN, AlGaN, InGaN, AlN, and InN, and may be an n-type semiconductor layer doped with a first conductive dopant (or an n-type dopant) such as Si, Ge, or Sn. However, the material configuring the first semiconductor layer 11 is not limited thereto, and other various materials may configure the first semiconductor layer 11. The first semiconductor layer 11 may include an upper surface contacting the active layer 12 along the length direction of the light-emitting element LD and a lower surface exposed to the outside.

The active layer 12 may be located on the first semiconductor layer 11 and may be formed in a single or multiple quantum well structure. For example, when the active layer 12 is formed in the multiple quantum well structure, in the active layer 12, a barrier layer, a strain reinforcing layer, and a well layer may be periodically and repeatedly stacked as one unit. The strain reinforcing layer may have a lattice constant less than that of the barrier layer to further reinforce resistance to a strain, for example, a compression strain, applied to the well layer. However, a structure of the active layer 12 is not limited to the above-described embodiments.

The active layer 12 may emit light of a wavelength of about 400 nm to about 900 nm, and may use a double hetero structure. In one or more embodiments, a clad layer doped with a conductive dopant may be formed on and/or under the active layer 12 along the length direction of the light-emitting element LD. For example, the clad layer may be formed of an AlGaN layer or an InAlGaN layer. According to one or more embodiments, a material such as AlGaN or InAlGaN may be used to form the active layer 12, and other various materials may configure the active layer 12. The active layer 12 may include a first surface contacting the first semiconductor layer 11 and a second surface contacting the second semiconductor layer 13.

When an electric field of a voltage (e.g., predetermined voltage) or more is applied to both ends of the light-emitting element LD, the light-emitting element LD emits light while an electron-hole pair is combined in the active layer 12. By controlling light emission of the light-emitting element LD by using such a principle, the light-emitting element LD may be used as a light source (or a light-emitting source) of various light-emitting devices including a pixel of the display device.

The second semiconductor layer 13 may be located on the second surface of the active layer 12 and may include a semiconductor layer of a type different from that of the first semiconductor layer 11. For example, the second semiconductor layer 13 may include at least one p-type semiconductor layer. For example, the second semiconductor layer 13 may include at least one semiconductor material among InAlGaN, GaN, AlGaN, InGaN, AlN, and InN, and may include a p-type semiconductor layer doped with a second conductive dopant (or a p-type dopant) such as Mg, Zn, Ca, Sr, or Ba. However, the material configuring the second semiconductor layer 13 is not limited thereto, and other various materials may configure the second semiconductor layer 13. The second semiconductor layer 13 may include a lower surface contacting the second surface of the active layer 12 along the length direction of the light-emitting element LD and an upper surface exposed to the outside.

In one or more embodiments, the first semiconductor layer 11 and the second semiconductor layer 13 may have thicknesses different from each other in the length direction of the light-emitting element LD. For example, the first semiconductor layer 11 may have a thickness relatively thicker than that of the second semiconductor layer 13 along the length direction of the light-emitting element LD. Therefore, the active layer 12 of the light-emitting element LD may be positioned more adjacently to the upper surface of the second semiconductor layer 13 than to the lower surface of the first semiconductor layer 11.

Although the first semiconductor layer 11 and the second semiconductor layer 13 are shown as being configured of one layer, the disclosure is not limited thereto. In one or more embodiments, according to the material of the active layer 12, each of the first semiconductor layer 11 and the second semiconductor layer 13 may further include at least one or more layers, for example, a clad layer and/or a tensile strain barrier reducing (TSBR) layer. The TSBR layer may be a strain relief layer located between semiconductor layers having different lattice structures and serving as a buffer for reducing a lattice constant difference. The TSBR layer may be configured of a p-type semiconductor layer such as p-GaInP, p-AlInP, and p-AlGaInP, but is not limited thereto.

According to one or more embodiments, the light-emitting element LD may further include a contact electrode (hereinafter referred to as a first contact electrode) located on the second semiconductor layer 13 in addition to the above-described first semiconductor layer 11, active layer 12, and second semiconductor layer 13. In addition, according to one or more other embodiments, the light-emitting element LD may further include another contact electrode (hereinafter referred to as a second contact electrode) located at one end of the first semiconductor layer 11.

Each of the first and second contact electrodes may be an ohmic contact electrode, but is not limited thereto. According to one or more embodiments, the first and second contact electrodes may be Schottky contact electrodes. The first and second contact electrodes may include a conductive material. For example, the first and second contact electrodes may include an opaque metal using chromium (Cr), titanium (Ti), aluminum (Al), gold (Au), nickel (Ni), an oxide thereof, an alloy thereof, and the like alone or in combination, but are not limited thereto. According to one or more embodiments, the first and second contact electrodes may also include transparent conductive oxide such as indium tin oxide (ITO), indium zinc oxide (IZO), zinc oxide (ZnOₓ), indium gallium zinc oxide (IGZO), and indium tin zinc oxide (ITZO). Here, the zinc oxide (ZnOₓ) may be zinc oxide (ZnO) and/or zinc peroxide (ZnO₂).

The materials included in the first and second contact electrodes may be the same as or different from each other. The first and second contact electrodes may be substantially transparent or translucent. Therefore, light generated by the light-emitting element LD may pass through each of the first and second contact electrodes and may be emitted to the outside of the light-emitting element LD. According to one or more embodiments, when the light generated by the light-emitting element LD does not pass through the first and second contact electrodes and is emitted to the outside of the light-emitting element LD through an area except for the both ends of the light-emitting element LD, the first and second contact electrodes may include an opaque metal.

In one or more embodiments, the light-emitting element LD may further include an insulating layer 14. However, according to one or more embodiments, the insulating layer 14 may be omitted and may be provided so as to cover only a portion of the first semiconductor layer 11, the active layer 12, and the second semiconductor layer 13.

The insulating layer 14 may reduce or prevent the likelihood of an electrical short that may occur when the active layer 12 contacts a conductive material other than the first and second semiconductor layers 11 and 13. In addition, the insulating layer 14 may reduce or minimize a surface defect of the light-emitting element LD to improve life and light emission efficiency of the light-emitting element LD. In addition, when a plurality of light-emitting elements LD are closely located, the insulating layer 14 may reduce or prevent the likelihood of an unwanted short that may occur between the light-emitting elements LD. When the active layer 12 may reduce or prevent the likelihood of a short with an external conductive material, presence or absence of the insulating layer 14 is not limited.

The insulating layer 14 may be provided in a form entirely surrounding an outer circumferential surface of the light-emitting stack including the first semiconductor layer 11, the active layer 12, and the second semiconductor layer 13.

In the above-described embodiments, the insulating layer 14 entirely surrounds the outer circumferential surface of each of the first semiconductor layer 11, the active layer 12, and the second semiconductor layer 13, but the disclosure is not limited thereto. According to one or more embodiments, when the light-emitting element LD includes the first contact electrode, the insulating layer 14 may entirely surround an outer circumferential surface of each of the first semiconductor layer 11, the active layer 12, the second semiconductor layer 13, and the first contact electrode. In addition, according to one or more other embodiments, the insulating layer 14 may not entirely surround the outer circumferential surface of the first contact electrode, or may surround only a portion of the outer circumferential surface of the first contact electrode and might not surround the rest of the outer circumferential surface of the first contact electrode. In addition, according to one or more embodiments, when the first contact electrode is located at the first end of the light-emitting element LD and the second contact electrode is located at the second end of the light-emitting element LD, the insulating layer 14 may expose at least one area of each of the first and second contact electrodes.

The insulating layer 14 may include a transparent insulating material. For example, the insulating layer 14 may include at least one insulating material selected from a group consisting of silicon oxide (SiOₓ), silicon nitride (SiNₓ), silicon oxynitride (SiOₓN_{y}), aluminum oxide (AlOₓ), titanium oxide (TiOₓ), hafnium oxide (HfOₓ), titanium strontium oxide (SrTiOₓ), cobalt oxide (CoₓO_{y}), magnesium oxide (MgO), zinc oxide (ZnOₓ), ruthenium oxide (RuOₓ), nickel oxide (NiO), tungsten oxide (WOₓ), tantalum oxide (TaOₓ), gadolinium oxide (GdOₓ), zirconium oxide (ZrOₓ), gallium oxide (GaOₓ), vanadium oxide (VₓO_{y}), ZnO:Al, ZnO:B, InₓO_{y}:H, niobium oxide (NbₓO_{y}), magnesium fluoride (MgFₓ), aluminum fluoride (AlFₓ), Alucone polymer film, titanium nitride (TiN), tantalum nitride (TaN), aluminum nitride (AlNₓ), gallium nitride (GaN), tungsten nitride (WN), hafnium nitride (HfN), niobium nitride (NbN), gadolinium nitride (GdN), zirconium nitride (ZrN), and vanadium nitride (VN), but the disclosure is not limited thereto, and various materials having insulating properties may be used as the material of the insulating layer 14.

The insulating layer 14 may be provided in a form of a single layer, or may be provided in a form of multiple layers including double layers. For example, when the insulating layer 14 is formed of the double layers including a first layer and a second layer sequentially stacked, the first layer and the second layer may be formed of different materials (or substances), and may be formed in different processes. According to one or more embodiments, the first layer and the second layer may be formed by a continuous process by including the same material.

According to one or more embodiments, the light-emitting element LD may be implemented with a light-emitting pattern of a core-shell structure. In this case, the above-described first semiconductor layer 11 may be positioned in a core, that is, a middle (or a center) of the light-emitting element LD, the active layer 12 may be provided and/or formed in a form surrounding the outer circumferential surface of the first semiconductor layer 11, and the second semiconductor layer 13 may be provided and/or formed in a form surrounding the outer circumferential surface of the active layer 12. In addition, the light-emitting element LD may further include a contact electrode surrounding at least one side of the second semiconductor layer 13. In addition, according to one or more embodiments, the light-emitting element LD may further include the insulating layer 14 provided on an outer circumferential surface of the light-emitting pattern of the core-shell structure and including a transparent insulating material. The light-emitting element LD implemented with the light-emitting pattern of the core-shell structure may be manufactured by a growth method.

A light-emitting unit (or a light-emitting device) including the above-described light-emitting element LD may be used as a light-emitting source (or a light source) of various display devices. The light-emitting element LD may be manufactured through a surface treatment process. For example, when a plurality of light-emitting elements LD are mixed in a fluid solution (or solvent) and supplied to each pixel area (e.g., an emission area of each pixel or an emission area of each sub-pixel), surface treatment may be performed on each of the light-emitting elements LD so that the light-emitting elements LD may be uniformly sprayed without being unevenly aggregated in the solution.

A light-emitting unit (or a light-emitting device) including the light-emitting element LD described above may be used in various types of electronic devices that require a light source, including a display device. For example, when a plurality of light-emitting elements LD are located in a pixel area of each pixel of a display panel, the light-emitting elements LD may be used as a light source of each pixel. However, an application field of the light-emitting element LD is not limited to the above-described example. For example, the light-emitting element LD may be used in other types of electronic devices that require a light source, such as a lighting device.

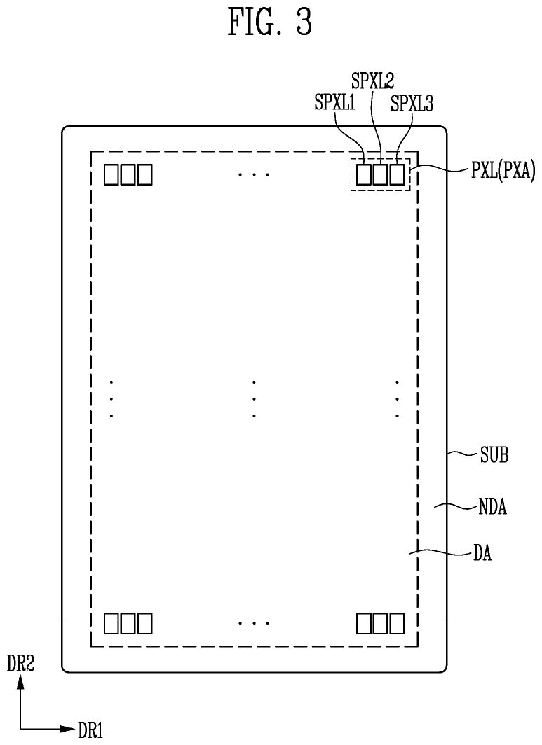

FIG. 3 is a plan view schematically illustrating a display device according to one or more embodiments.

In FIG. 3, for convenience, a structure of the display device is schematically shown centering on a display area DA where an image is displayed.

When the display device is an electronic device to which a display surface is applied to at least one surface, such as a smartphone, a television, a tablet PC, a mobile phone, a video phone, an e-book reader, a desktop PC, a laptop PC, a netbook computer, a workstation, a server, a PDA, a portable multimedia player (PMP), an MP3 player, a medical device, a camera, or wearable device, the disclosure may be applied to the display device.

Referring to FIGS. 1 to 3, the display device may include a substrate SUB, a plurality of pixels PXL provided on the substrate SUB and each including at least one light-emitting element LD, a driver provided on the substrate SUB for driving the pixels PXL, and a line unit connecting the pixels PXL and the driver.

The display device may be classified into a passive matrix type display device and an active matrix type display device according to a method of driving the light-emitting element LD. For example, when the display device is implemented as the active matrix type display device, each of the pixels PXL may include a driving transistor that controls a current amount supplied to the light-emitting element LD, a switching transistor that transfers a data signal to the driving transistor, and the like.

The display device may be provided in various shapes, and for example, may be provided in a rectangular plate shape having two pairs of sides parallel to each other, but the disclosure is not limited thereto. When the display device is provided in the rectangular plate shape, any one pair of sides of the two pairs of sides may be provided to be longer than the other pair of sides. For convenience, a case where the display device has a rectangular shape having a pair of long sides and a pair of short sides is disclosed. In addition, an extension direction of the long side is denoted as a second direction DR2, and an extension direction of the short side is denoted as a first direction DR1. In the display device provided in the rectangular plate shape, a corner portion in which one long side and one short side contact (or meet) may have a round shape, but is not limited thereto.

The substrate SUB may include the display area DA and a non-display area NDA.

The display area DA may be an area where the pixels PXL displaying an image are provided. The non-display area NDA may be an area in which the driver for driving the pixels PXL and a portion of the line unit connecting the pixels PXL and the driver are provided.

The non-display area NDA may be positioned adjacent to the display area DA. The non-display area NDA may be provided on at least one side of the display area DA. For example, the non-display area NDA may surround a circumference (or an edge) of the display area DA. The line unit connected to the pixels PXL and the driver connected to the line unit and driving the pixels PXL may be provided in the non-display area NDA.

The line unit may electrically connect the driver and the pixels PXL. The line unit may include a fan-out line connected to one or more signal lines. The signal lines may be for providing a signal to the pixel PXL and connected to one or more respective pixels PXL, and may be, for example, a scan line, a data line, an emission control line, or the like. In addition, according to one or more embodiments, the line unit may include a fan-out line connected to signal lines connected to each pixel PXL to compensate for an electrical characteristic change of each pixel PXL in real time, for example, a control line, a sensing line, or the like. Additionally, the line unit may include a fan-out line connected to power lines providing a voltage (e.g., predetermined voltage) to each pixel PXL and connected to each pixel PXL.

The substrate SUB may include a transparent insulating material and may transmit light. The substrate SUB may be a rigid substrate or a flexible substrate.

One area on the substrate SUB may be provided as the display area DA and thus the pixels PXL may be located. The remaining area on the substrate SUB may be provided as the non-display area NDA. For example, the substrate SUB may include the display area DA including pixel areas in which each pixel PXL is located, and the non-display area NDA located around the display area DA (or adjacent to the display area DA).

Each of the pixels PXL may be provided in the display area DA on the substrate SUB. In one or more embodiments, the pixels PXL may be arranged in the display area DA in a stripe arrangement structure or the like, but are not limited thereto.

A first sub-pixel SPXL1, a second sub-pixel SPXL2, and a third sub-pixel SPXL3 may be provided in a pixel area PXA in which each of the pixels PXL is provided. In one or more embodiments, the first sub-pixel SPXL1 may be a red pixel (or a red sub-pixel), the second sub-pixel SPXL2 may be a green pixel (or a green sub-pixel), and the third sub-pixel SPXL3 may be a blue pixel (or a blue sub-pixel). However, the disclosure is not limited thereto, and according to one or more embodiments, the second sub-pixel SPXL2 may be a red pixel, the first sub-pixel SPXL1 may be a green pixel, and the third sub-pixel SPXL3 may be a blue pixel. In addition, according to one or more other embodiments, the third sub-pixel SPXL3 may be a red pixel, the first sub-pixel SPXL1 may be a green pixel, and the second sub-pixel SPXL2 may be a blue pixel.

The first sub-pixel SPXL1 may include a first pixel circuit and a first light-emitting unit, the second sub-pixel SPXL2 may include a second pixel circuit and a second light-emitting unit, and the third sub-pixel SPXL3 may include a third pixel circuit and a third light-emitting unit.

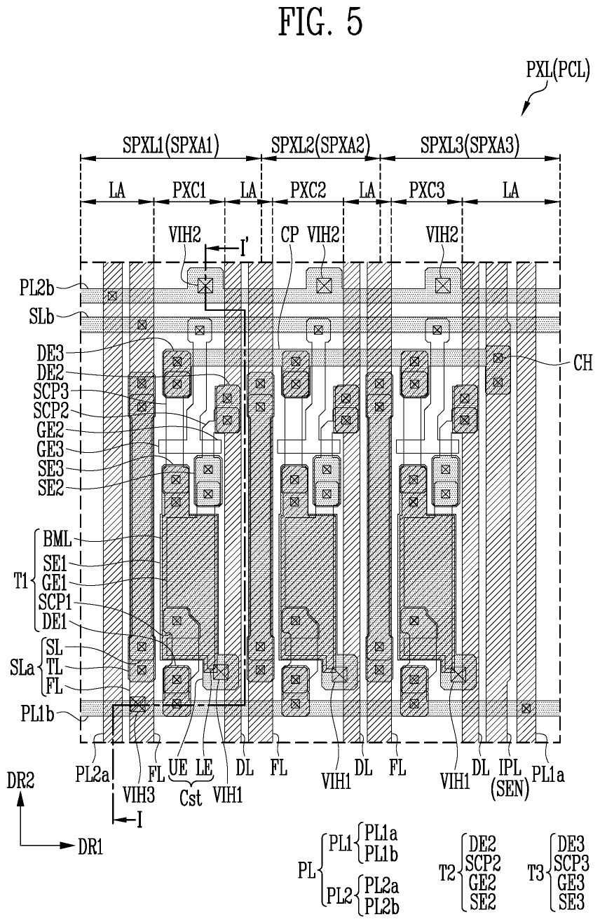

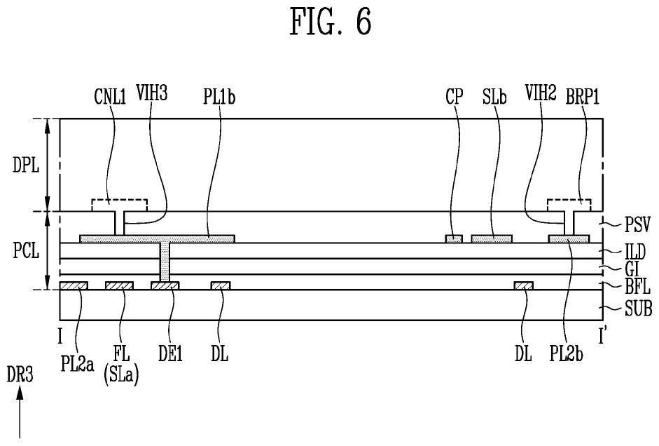

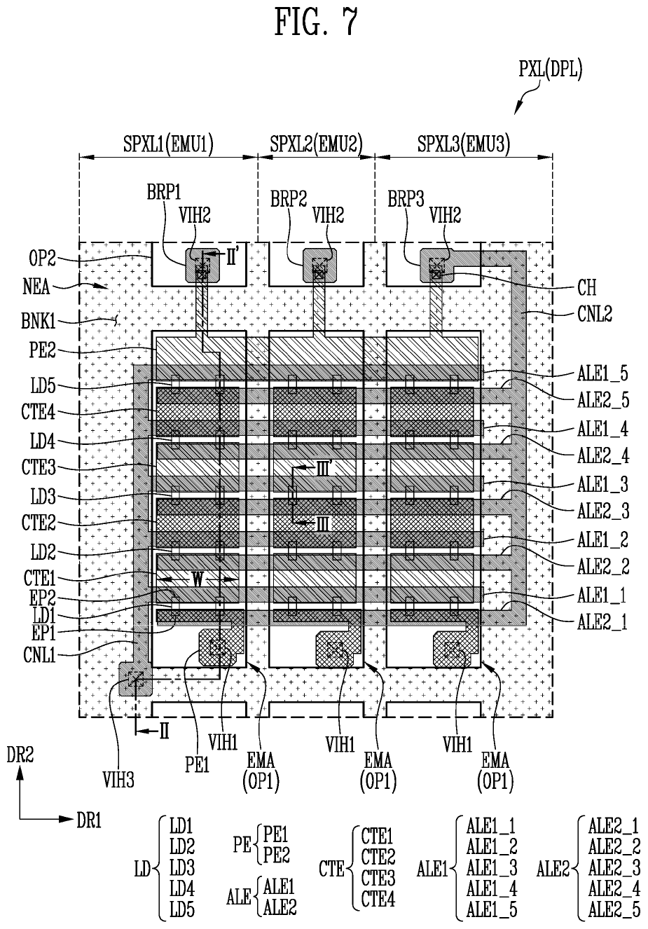

The first, second, and third pixel circuits and the first, second, and third light-emitting units may be located in different layers and may overlap each other. For example, the first, second, and third pixel circuits may be located in a pixel circuit layer (e.g., pixel circuit layer PCL of FIGS. 5 and 6) of a sub-pixel area in which each sub-pixel is located. In addition, the first, second, and third light-emitting units may be located in a display element layer (e.g., display element layer DPL of FIGS. 7 to 13) overlapping the pixel circuit layer PCL in a corresponding sub-pixel.

A first alignment electrode (or a first alignment line) and a second alignment electrode (or a second alignment line) spaced apart from each other may be located in the first, second, and third light-emitting units. The light-emitting element LD may be located between the first alignment electrode and the second alignment electrode. Configurations located in the pixel area PXA are described later with reference to FIGS. 5 to 18.

Each pixel PXL may include at least one light-emitting element LD driven by corresponding scan signal and data signal. The light-emitting element LD may have a size as small as a nano scale (or nano meter) to a micro scale (or micro meter) and may be connected in parallel with adjacently located light-emitting elements, but the disclosure is not limited thereto. The light-emitting element LD may configure a light source of each pixel PXL (or each sub-pixel).

Each pixel PXL (or each sub-pixel) may include at least one light source driven by a signal (e.g., a predetermined signal, for example, a scan signal, a data signal, and the like) and/or power (e.g., predetermined power, for example, first driving power, second driving power, and the like), for example, the light-emitting element LD shown in FIGS. 1 and 2. However, in one or more embodiments, the type of the light-emitting element LD that may be used as the light source of each pixel PXL (or each sub-pixel) is not limited thereto.

The driver may supply a signal (e.g., predetermined signal) and power (e.g., predetermined power) to each pixel PXL (or each sub-pixel) through the line unit, and thus may control driving of each pixel PXL (or each sub-pixel).

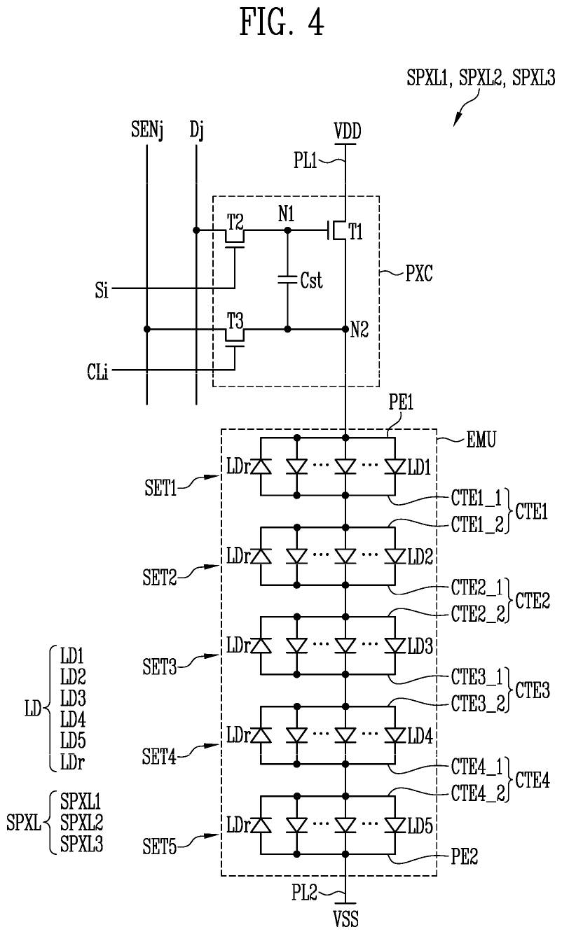

FIG. 4 is a schematic circuit diagram illustrating an electrical connection relationship between components included in each of the first to third sub-pixels shown in FIG. 3 according to one or more embodiments.

For example, FIG. 4 shows the electrical connection relationship between the components included in each of the first to third sub-pixels SPXL1, SPXL2, and SPXL3 applicable to an active matrix type display device according to one or more embodiments. However, a connection relationship between each of components included in the first to third sub-pixels SPXL1, SPXL2, and SPXL3 is not limited thereto. In the following embodiments, the first sub-pixel SPXL1, the second sub-pixel SPXL2, and the third sub-pixel SPXL3 are collectively referred to as the sub-pixel SPXL or the sub-pixels SPXL.

Referring to FIGS. 1 to 4, the sub-pixel SPXL may include a light-emitting unit EMU (or an emission unit) that generates light of a luminance corresponding to a data signal. In addition, the sub-pixel SPXL may selectively further include a pixel circuit PXC for driving the light-emitting unit EMU.

According to one or more embodiments, the light-emitting unit EMU may include a plurality of light-emitting elements LD connected in parallel between a first power line PL1 connected to first driving power VDD to which a voltage of the first driving power VDD is applied, and a second power line PL2 connected to second driving power VSS to which a voltage of the second driving power VSS is applied. For example, the light-emitting unit EMU may include a first electrode PE1 (or a first pixel electrode) connected to the first driving power VDD through the pixel circuit PXC and the first power line PL1, a second electrode PE2 (or a second pixel electrode) connected to the second driving power VSS through the second power line PL2, and the plurality of light-emitting elements LD connected in parallel in the same direction between the first electrode PE1 and the second electrode PE2. In one or more embodiments, the first electrode PE1 may be an anode, and the second electrode PE2 may be a cathode.

Each of the light-emitting elements LD included in the light-emitting unit EMU may include the first end connected to the first driving power VDD through the first electrode PE1, and the second end connected to the second driving power VSS through the second electrode PE2. The first driving power VDD and the second driving power VSS may have different potentials. For example, the first driving power VDD may be set as high potential power, and the second driving power VSS may be set as low potential power. At this time, a potential difference between the first driving power VDD and the second driving power VSS may be set as a threshold voltage or more of the light-emitting elements LD during an emission period of the sub-pixel SPXL.

As described above, the respective light-emitting elements LD, which are connected in parallel in the same direction (e.g., a forward direction) between the first electrode PE1 and the second electrode PE2 to which the voltages of the different power are supplied, may configure respective effective light sources.

The light-emitting elements LD of the light-emitting unit EMU may emit light with a luminance corresponding to a driving current supplied through a corresponding pixel circuit PXC. For example, a driving current corresponding to a grayscale value of corresponding frame data of the pixel circuit PXC may be supplied to the light-emitting unit EMU during each frame period. The driving current supplied to the light-emitting unit EMU may be divided and flow to each of the light-emitting elements LD. Therefore, each of the light-emitting elements LD may emit light with a luminance corresponding to the current flowing through the light-emitting element LD, and thus the light-emitting unit EMU may emit light of the luminance corresponding to the driving current.

In the above-described embodiments, one or more embodiments in which respective ends of the light-emitting elements LD are connected in the same direction between the first and second driving power VDD and VSS is described, but the disclosure is not limited thereto. According to one or more embodiments, the light-emitting unit EMU may further include at least one ineffective light source, for example, a reverse light-emitting element LDr, in addition to the light-emitting elements LD configuring each effective light source. The reverse light-emitting element LDr may be connected in parallel between the first and second electrodes PE1 and PE2 together with the light-emitting elements LD configuring the effective light sources, and may be connected between the first and second electrodes PE1 and PE2 in a direction opposite to the light-emitting elements LD. The reverse light-emitting element LDr maintains an inactive state even though a driving voltage (e.g., predetermined driving voltage, for example, a driving voltage of a forward direction) is applied between the first and second electrodes PE1 and PE2, and thus a current substantially does not flow through the reverse light-emitting element LDr.

The pixel circuit PXC may be connected to a scan line Si and a data line Dj of the sub-pixel SPXL. In addition, the pixel circuit PXC may be connected to a control line CLi and a sensing line SENj of the sub-pixel SPXL. For example, when the sub-pixel SPXL is located in an i-th row and a j-th column of the display area DA, the pixel circuit PXC of the sub-pixel SPXL may be connected to the i-th scan line Si and the j-th data line Dj, the i-th control line CLi, and the j-th sensing line SENj of the display area DA.

The pixel circuit PXC may include first to third transistors T1 to T3 and a storage capacitor Cst.

The first transistor T1 may be a driving transistor for controlling the driving current applied to the light-emitting unit EMU, and may be connected between the first driving power VDD and the light-emitting unit EMU. For example, a first terminal of the first transistor T1 may be electrically connected to the first driving power VDD through the first power line PL1, a second terminal of the first transistor T1 may be electrically connected to a second node N2, and a gate electrode of the first transistor T1 may be electrically connected to a first node N1. The first transistor T1 may control an amount of the driving current applied from the first driving power VDD to the light-emitting unit EMU through the second node N2 according to a voltage applied to the first node N1. In one or more embodiments, the first terminal of the first transistor T1 may be a drain electrode, and the second terminal of the first transistor T1 may be a source electrode, but the disclosure is not limited thereto. According to one or more embodiments, the first terminal may be a source electrode and the second terminal may be a drain electrode.

The second transistor T2 may be a switching transistor that selects the sub-pixel SPXL in response to a scan signal and activates the sub-pixel SPXL, and may be connected between the data line Dj and the first node N1. A first terminal of the second transistor T2 may be connected to the data line Dj, a second terminal of the second transistor T2 may be connected to the first node N1, and a gate electrode of the second transistor T2 may be connected to the scan line Si. The first terminal and the second terminal of the second transistor T2 may be different terminals. For example, when the first terminal is a drain electrode, the second terminal may be a source electrode.

The second transistor T2 may be turned on when a scan signal of a gate-on voltage (e.g., a high level voltage) is supplied from the scan line Si to thereby electrically connect the data line Dj and the first node N1. The first node N1 may be a point where the second terminal of the second transistor T2 and the gate electrode of the first transistor T1 are connected, and the second transistor T2 may transmit a data signal to the gate electrode of the first transistor T1.

The third transistor T3 may connect the first transistor T1 to the sensing line SENj to obtain a sensing signal through the sensing line SENj, and may detect a characteristic of the sub-pixel SPXL including a threshold voltage and the like of the first transistor T1 using the sensing signal. Information on the characteristic of the sub-pixel SPXL may be used to convert image data so that a characteristic deviation between the sub-pixels SPXL may be compensated. A second terminal of the third transistor T3 may be connected to the second terminal of the first transistor T1, a first terminal of the third transistor T3 may be connected to the sensing line SENj, and a gate electrode of the third transistor T3 may be connected to the control line CLi. In addition, in one or more embodiments, the first terminal of the third transistor T3 may be connected to initialization power. The third transistor T3 may be an initialization transistor capable of initializing the second node N2, and may be turned on when a sensing control signal is supplied from the control line CLi to thereby transmit a voltage of the initialization power to the second node N2. Accordingly, a second storage electrode of the storage capacitor Cst electrically connected to the second node N2 may be initialized.

The storage capacitor Cst may include a first storage electrode (or a lower electrode) and a second storage electrode (or an upper electrode). The first storage electrode may be electrically connected to the first node N1, and the second storage electrode may be electrically connected to the second node N2. The storage capacitor Cst charges a data voltage corresponding to the data signal supplied to the first node N1 during one frame period. Accordingly, the storage capacitor Cst may store a voltage corresponding to a voltage difference between a voltage of the gate electrode of the first transistor T1 and a voltage of the second node N2.

The light-emitting unit EMU may be configured to include at least one series stage including the plurality of light-emitting elements LD electrically connected in parallel with each other. In one or more embodiments, the light-emitting unit EMU may be configured in a series/parallel mixed structure as shown in FIG. 4. For example, the light-emitting unit EMU may be configured to include a first series stage SET1, a second series stage SET2, a third series stage SET3, a fourth series stage SET4, and a fifth series stage SET5.

The light-emitting unit EMU may include the first, second, third, fourth, and fifth series stages SET1, SET2, SET3, SET4, and SET5 sequentially connected between the first driving power VDD and the second driving power VSS. Each of the first, second, third, fourth, and fifth series stages SET1, SET2, SET3, SET4, and SET5 may include two respective electrodes PE1 and CTE1_1, CTE1_2 and CTE2_1, CTE2_2 and CTE3_1, CTE3_2 and CTE4_1, and CTE4_2 and PE2 configuring an electrode pair of a corresponding series stage, and may include respective ones of the plurality of light-emitting elements LD connected in parallel in the same direction between the two electrodes PE1 and CTE1_1, CTE1_2 and CTE2_1, CTE2_2 and CTE3_1, CTE3_2 and CTE4_1, and CTE4_2 and PE2.

The first series stage SET1 (or a first stage) may include the first electrode PE1 (or the first pixel electrode), the (1-1)-th intermediate electrode CTE1_1, and at least one first light-emitting element LD1 connected between the first electrode PE1 and the (1-1)-th intermediate electrode CTE1_1. In addition, the first series stage SET1 may include a reverse light-emitting element LDr connected in a direction opposite to the first light-emitting element LD1 between the first electrode PE1 and the (1-1)-th intermediate electrode CTE1_1.

The second series stage SET2 (or a second stage) may include the (1_2)-th intermediate electrode CTE1_2 and the (2_1)-th intermediate electrode CTE2_1, and at least one second light-emitting element LD2 connected between the (1_2)-th intermediate electrode CTE1_2 and the (2_1)-th intermediate electrode CTE2_1. In addition, the second series stage SET2 may include a reverse light-emitting element LDr connected in a direction opposite to the second light-emitting element LD2 between the (1_2)-th intermediate electrode CTE1_2 and the (2_1)-th intermediate electrode CTE2_1.

The (1_1)-th intermediate electrode CTE1_1 of the first series stage SET1 and the (1_2)-th intermediate electrode CTE1_2 of the second series stage SET2 may be integrally provided and connected to each other. For example, the (1_1)-th intermediate electrode CTE1_1 and the (1_2)-th intermediate electrode CTE1_2 may configure a first intermediate electrode CTE1 electrically connecting the successive first series stage SET1 and second series stage SET2. When the (1_1)-th intermediate electrode CTE1_1 and the (1_2)-th intermediate electrode CTE1_2 are integrally provided, the (1_1)-th intermediate electrode CTE1_1 and the (1_2)-th intermediate electrode CTE1_2 may be different areas of the first intermediate electrode CTE1.

The third series stage SET3 (or a third stage) may include the (2-2)-th second intermediate electrode CTE2_2 and the (3-1)-th intermediate electrode CTE3_1, and at least one third light-emitting element LD3 electrically connected between the (2-2)-th second intermediate electrode CTE2_2 and the (3-1)-th intermediate electrode CTE3_1. In addition, the third series stage SET3 may include a reverse light-emitting element LDr connected in a direction opposite to the third light-emitting element LD3 between the (2-2)-th second intermediate electrode CTE2_2 and the (3-1)-th intermediate electrode CTE3_1.

The (2_1)-th intermediate electrode CTE2_1 of the second series stage SET2 and the (2_2)-th intermediate electrode CTE2_2 of the third series stage SET3 may be integrally provided and connected to each other. For example, the (2_1)-th intermediate electrode CTE2_1 and the (2_2)-th intermediate electrode CTE2_2 may configure a second intermediate electrode CTE2 electrically connecting the successive second series stage SET2 and third series stage SET3. When the (2_1)-th intermediate electrode CTE2_1 and the (2_2)-th intermediate electrode CTE2_2 are integrally provided, the (2_1)-th intermediate electrode CTE2_1 and the (2_2)-th intermediate electrode CTE2_2 may be different areas of the second intermediate electrode CTE2.

The fourth series stage SET4 (or a fourth stage) may include the (3-2)-th intermediate electrode CTE3_2 and the (4-1)-th intermediate electrode CTE4_1, and at least one fourth light-emitting element LD4 electrically connected between the (3-2)-th intermediate electrode CTE3_2 and the (4-1)-th intermediate electrode CTE4_1. In addition, the fourth series stage SET4 may include a reverse light-emitting element LDr connected in a direction opposite to the fourth light-emitting element LD4 between the (3-2)-th intermediate electrode CTE3_2 and the (4-1)-th intermediate electrode CTE4_1.

The (3-1)-th intermediate electrode CTE3_1 of the third series stage SET3 and the (3-2)-th intermediate electrode CTE3_2 of the fourth series stage SET4 may be integrally provided and connected to each other. For example, the (3-1)-th intermediate electrode CTE3_1 and the (3-2)-th intermediate electrode CTE3_2 may configure a third intermediate electrode CTE3 electrically connecting the successive third series stage SET3 and fourth series stage SET4. When the (3-1)-th intermediate electrode CTE3_1 and the (3-2)-th intermediate electrode CTE3_2 are integrally provided, the (3-1)-th intermediate electrode CTE3_1 and the (3-2)-th intermediate electrode CTE3_2 may be different areas of the intermediate electrode CTE3.

The fifth series stage SET5 (or a fifth stage) may include the (4-2)-th intermediate electrode CTE4_2 and the second electrode PE2, and one fifth light-emitting element LD5 electrically connected between the (4-2)-th intermediate electrode CTE4_2 and the second electrode PE2. In addition, the fifth series stage SET5 may include a reverse light-emitting element LDr connected in a direction opposite to the fifth light-emitting element LD5 between the (4-2)-th intermediate electrode CTE4_2 and the second electrode PE2.

The (4-1)-th intermediate electrode CTE4_1 of the fourth series stage SET4 and the (4-2)-th intermediate electrode CTE4_2 of the fifth series stage SET5 may be integrally provided and connected to each other. For example, the (4-1)-th intermediate electrode CTE4_1 and the (4-2)-th intermediate electrode CTE4_2 may configure a fourth intermediate electrode CTE4. When the (4-1)-th intermediate electrode CTE4_1 and the (4-2)-th intermediate electrode CTE4_2 are integrally provided, the (4-1)-th intermediate electrode CTE4_1 and the (4-2)-th intermediate electrode CTE4_2 may be different areas of the intermediate electrode CTE4.

In the above-described embodiments, the first electrode PE1 of the first series stage SET1 may be an anode of the light-emitting unit EMU, and the second electrode PE2 of the fifth series stage SET5 may be a cathode of the light-emitting unit EMU.

As described above, the light-emitting unit EMU of the sub-pixel SPXL including the series stages SET1, SET2, SET3, SET4, and SET5 (or the light-emitting elements LD) connected in a series/parallel mixed structure may suitably adjust a driving current/voltage condition according to an applied product specification.

For example, the light-emitting unit EMU of the sub-pixel SPXL including the series stages SET1, SET2, SET3, SET4, and SET5 (or the light-emitting elements LD) connected in the series/parallel mixed structure may reduce a driving current compared to the light-emitting unit of a structure in which the light-emitting elements LD are connected only in parallel. In addition, the light-emitting unit EMU of the sub-pixel SPXL including the series stages SET1, SET2, SET3, SET4, and SET5 connected in the series/parallel mixed structure may reduce a driving voltage applied to both ends of the light-emitting unit EMU compared to the light-emitting unit in which all of the same number of light-emitting elements LD are connected in series. Furthermore, the light-emitting unit EMU of the sub-pixel SPXL including the series stages SET1, SET2, SET3, SET4, and SET5 (or the light-emitting elements LD connected in the series/parallel mixed structure may include a greater number of light-emitting elements LD between the same number of electrodes PE1, CTE1_1, CTE1_2, CTE2_1, CTE2_2, CTE3_1, CTE3_2, CTE4_1, CTE4_2, and PE2 compared to the light-emitting unit of a structure in which all of the series stages (or stages) are connected in series. In this case, light output efficiency of the light-emitting elements LD may be improved, and even though a defect occurs in a corresponding series stage (or stage), a ratio of the light-emitting elements LD that do not emit light due to the defect may be relatively reduced, and thus a reduction of the light emission efficiency of the light-emitting elements LD may be alleviated.

FIG. 5 is a plan view schematically illustrating the pixel circuit layer PCL of the pixel PXL shown in FIG. 3, and FIG. 6 is a schematic cross-sectional view taken along the line I˜I′ of FIG. 5.

For example, FIG. 5 schematically shows one or more embodiments of a structure of the pixel circuit layer PCL based on the pixel area PXA in which the pixel PXL of FIG. 3 is located.

In FIG. 5, for convenience of description, a horizontal direction on a plane is indicated as a first direction DR1 and a vertical direction on the plane is indicated as a second direction DR2.

In FIG. 6, the pixel circuit layer PCL of the pixel PXL is simplified, such as showing each electrode as a single layer electrode and each insulating layer as only a single layer insulating layer, but the disclosure is not limited thereto. In FIG. 6, a vertical direction (or a thickness direction of the substrate SUB) on a cross-section is indicated as a third direction DR3.

In the following embodiments, not only components included in the pixel PXL shown in FIGS. 5 and 6, but also an area in which the components are provided (or positioned) are collectively referred to as the pixel PXL.

Referring to FIGS. 1 to 6, the pixel circuit layer PCL of the pixel PXL may include a plurality of pixel circuits PXC1, PXC2, and PXC3 located in the pixel area PXA. For example, the pixel circuit layer PCL may include a first pixel circuit PXC1 located in a first sub-pixel area SPXA1, a second pixel circuit PXC2 located in a second sub-pixel area SPXA2, and a third pixel circuit PXC3 located in a third sub-pixel area SPXA3. The first sub-pixel area SPXA1 may be an area of the pixel area PXA in which the first sub-pixel SPXL1 is positioned, the second sub-pixel area SPXA2 may be an area of the pixel area PXA in which the second sub-pixel SPXL2 is positioned, and the third sub-pixel area SPXA3 may be an area of the pixel area PXA in which the third sub-pixel SPX3 is positioned.

In one or more embodiments, the first sub-pixel area SPXA1 may include a line area LA positioned on a left side and/or a right side of the first pixel circuit PXC1. The second sub-pixel area SPXA2 may include a line area LA positioned on a left side and/or a right side of the second pixel circuit PXC2. The third sub-pixel area SPXA3 may include a line area LA positioned on a left side and/or a right side of the third pixel circuit PXC3. The line area LA may be an area in which lines extending in the second direction DR2 are located in a corresponding sub-pixel area. For example, in the line area LA, a second vertical power line PL2a extending in the second direction DR2, a first scan line SLa, a data line DL, an initialization power line IPL, and a first vertical power line PL1a may be located.

The pixel circuit layer PCL may include at least one insulating layer located on the substrate SUB. For example, the pixel circuit layer PCL may include a buffer layer BFL, a gate insulating layer GI, an interlayer insulating layer ILD, and a passivation layer PSV sequentially stacked on the substrate SUB along the third direction DR3.

The buffer layer BFL may be entirely located on the substrate SUB. The buffer layer BFL may reduce or prevent an impurity from diffusing into the transistors T1, T2, and T3 included in the first to third pixel circuits PXC1, PXC2, and PXC3. The buffer layer BFL may be an inorganic insulating layer including an inorganic material. The buffer layer BFL may include at least one of metal oxides such as silicon nitride (SiNₓ), silicon oxide (SiOₓ), silicon oxynitride (SiOₓN_{y}), and aluminum oxide (AlOₓ). The buffer layer BFL may be provided as a single layer, but may also be provided as multiple layers of at least double layers. When the buffer layer BFL is provided as the multiple layers, each layer may be formed of the same material or may be formed of different materials. In one or more embodiments, the buffer layer BFL may be omitted according to a material, a process condition, and the like of the substrate SUB.

The gate insulating layer GI may be entirely located on the buffer layer BFL. The gate insulating layer GI may include the same material as the above-described buffer layer BFL or may include a suitable material from the configuration material of the buffer layer BFL. For example, the gate insulating layer GI may be an inorganic insulating layer including an inorganic material.

The interlayer insulating layer ILD may be entirely provided and/or formed on the gate insulating layer GI. The interlayer insulating layer ILD may include the same material as the gate insulating layer GI, or may include one or more materials selected from the configuration material of the gate insulating layer GI.

The passivation layer PSV may be entirely provided and/or formed on the interlayer insulating layer ILD. The passivation layer PSV may be an inorganic insulating layer including an inorganic material, or an organic insulating layer including an organic material. The inorganic insulating layer may include, for example, at least one of metal oxides such as silicon oxide (SiOₓ), silicon nitride (SiNₓ), silicon oxynitride (SiOₓN_{y}), and aluminum oxide (AlOₓ). The organic insulating layer may include, for example, at least one of an acrylic resin (polyacrylates resin), an epoxy resin, a phenolic resin, a polyamide resin, a polyimide resin, an unsaturated polyester resin, a poly-phenylene ethers resin, a poly-phenylene sulfides resin, and a benzocyclobutene resin.

The passivation layer PSV may be partially opened to expose some configurations of each of the first, second, and third pixel circuits PXC1, PXC2, and PXC3. For example, the passivation layer PSV may be partially opened to include a first via hole VIH1 (e.g., a first through hole, or a first contact hole) exposing each of a first upper electrode UE of the first pixel circuit PXC1, a second upper electrode UE of the second pixel circuit PXC2, and a third upper electrode UE of the third pixel circuit PXC3. The passivation layer PSV may be partially opened to include three second via holes VIH2 exposing one area of a second horizontal power line PL2b of the pixel circuit layer PCL. In addition, the passivation layer PSV may be partially opened to include one third via holes VIH3 exposing one area of a first horizontal power line PL1b of the pixel circuit layer PCL.

The pixel circuit layer PCL may include at least one conductive layer located between the above-described insulating layers. For example, the pixel circuit layer PCL may include a first conductive layer located between the substrate SUB and the buffer layer BFL, a second conductive layer located on the gate insulating layer GI, and a third conductive layer located on the interlayer insulating layer ILD.

The first conductive layer may be formed in a single layer formed of a group consisting of copper (Cu), molybdenum (Mo), tungsten (W), aluminum neodymium (AlNd), titanium (Ti), aluminum (Al), silver (Ag), and an alloy thereof alone or a mixture thereof, or may be formed in a double layer or multiple layer structure of molybdenum (Mo), titanium (Ti), copper (Cu), aluminum (Al), or silver (Ag), which is a low-resistance material to reduce a line resistance. Each of the second and third conductive layers may include the same material as the first conductive layer, or may include one or more materials suitable from the configuration material of the first conductive layer, but is not limited thereto.

In one or more embodiments, the substrate SUB may include a transparent insulating material, and may transmit light. The substrate SUB may be a rigid substrate or a flexible substrate.

For example, the rigid substrate may be one of a glass substrate, a quartz substrate, a glass ceramic substrate, and a crystalline glass substrate.

The flexible substrate may be one of a film substrate and a plastic substrate including a polymer organic material. For example, the flexible substrate may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate.

The pixel circuit layer PCL may further include a plurality of contact holes CH for connecting circuit elements (e.g., predetermined circuit elements), electrodes, and/or lines located in the pixel circuit layer PCL on the substrate SUB to each other. For convenience, in FIG. 5, only one contact hole CH is denoted by a symbol representing the contact holes CH for connecting corresponding elements in the pixel circuit layer PCL.

The pixel circuit layer PCL may further include lines located on the substrate SUB and electrically connected to the pixels PXL. For example, the pixel circuit layer PCL may include scan lines SLa and SLb, the data line DL, a power line PL, and the initialization power line IPL.

The scan lines SLa and SLb may include a first scan line SLa and a second scan line SLb spaced apart from each other.

The first scan line SLa may be located in each of the first, second, and third sub-pixel areas SPXA1, SPXA2, and SPXA3, and may extend in the second direction DR2. A signal (e.g., predetermined signal, for example, a scan signal or a control signal) may be applied to the first scan line SLa. In one or more embodiments, the first scan line SLa may be provided as multiple layers in which a first layer FL, a second layer SL, and a third layer TL are sequentially stacked. The first layer FL may be the first conductive layer, the second layer SL may be the second conductive layer, and the third layer TL may be the third conductive layer. The first layer FL, the second layer SL, and the third layer TL may be connected to each other through a corresponding contact hole CH. According to one or more embodiments, the first scan line SLa may be provided as a single layer including only the first layer FL configured of the first conductive layer. The scan signal and/or the control signal may be supplied to the first scan line SLa.

The second scan line SLb may be commonly provided (or located) to the first, second, and third sub-pixel areas SPXA1, SPXA2, and SPXA3, and may extend in the second direction DR2 crossing an extension direction of the first scan line SLa. The second scan line SL2b may be configured as a single layer including the third conductive layer. The second scan line SLb may be electrically connected to the first scan line SLa through a corresponding contact hole CH. For example, in the first sub-pixel area SPXA1, the second scan line SLb may be electrically connected to the first scan line SLa located in the first sub-pixel area SPXA1 through the corresponding contact hole CH. The second scan line SLb may be electrically connected to some configurations of each of the first, second, and third pixel circuits PXC1, PXC2, and PXC3. For example, the second scan line SLb may be electrically connected to the second and third transistors T2 and T3 of each of the first, second, and third pixel circuits PXC1, PXC2, and PXC3 through the corresponding contact hole CH.

The data line DL may be located in each of the first, second, and third sub-pixel areas SPXA1, SPXA2, and SPXA3, and may extend in the second direction DR2. A data signal may be applied to the data line DL. In one or more embodiments, the data line DL may be configured as a single layer including the first conductive layer, but is not limited thereto. According to one or more embodiments, the data line DL may be configured as multiple layers in which the first, second, and third conductive layers are sequentially stacked. The data line DL may be electrically connected to the second transistor T2 of each of the first, second, and third pixel circuits PXC1, PXC2, and PXC3 through a corresponding contact hole CH.

The power line PL may include the first power line PL1 and the second power line PL2 spaced apart from each other.

The first power line PL1 may include a first vertical power line PL1a located in the third sub-pixel area SPXA3 and extending in the second direction DR2, and a first horizontal power line PL1b commonly located in the first, second, and third sub-pixel areas SPXA1, SPXA2, and SPXA3 and extending in the first direction DR1. The voltage of the first driving power VDD may be applied to the first vertical power line PL1a.

The first vertical power line PL1a and the first horizontal power line PL1b may be located in different layers, and may be electrically connected through a corresponding contact hole CH. For example, the first vertical power line PL1a may be the first conductive layer, the first horizontal power line PL1b may be the third conductive layer, and the first vertical power line PL1a and the first horizontal power line PL1b may be electrically connected to each other through the corresponding contact hole CH. The first power line PL1 may have a mesh structure by the first vertical power line PL1a and the first horizontal power line PL1b connected to each other.

In one or more embodiments, the first horizontal power line PL1b may be electrically connected to a partial configuration of the display element layer DPL through the third via hole VIH3 passing through the passivation layer PSV in the first sub-pixel area SPXA1. For example, the first horizontal power line PL1b may be electrically connected to a first connection line CNL1 of the display element layer DPL through the third via hole VIH3 passing through the passivation layer PSV in the first sub-pixel area SPXA1.

The second power line PL2 may include a second vertical power line PL2a located in the first sub-pixel area SPXA1 and extending in the second direction DR2, and a second horizontal power line PL2b commonly located in the first, second, and third sub-pixel areas SPXA1, SPXA2, and SPXA3 and extending in the first direction DR1. The voltage of the second driving power VSS may be applied to the second vertical power line PL2a.

The second vertical power line PL2a and the second horizontal power line PL2b may be located in different layers, and may be electrically connected through a corresponding contact hole CH. For example, the second vertical power line PL2a may be the first conductive layer, the second horizontal power line PL2b may be the third conductive layer, and the second vertical power line PL2a and the second horizontal power line PL2b may be electrically connected to each other through the corresponding contact hole CH. The second power line PL2 may have a mesh structure by the second vertical power line PL2a and the second horizontal power line PL2b connected to each other.

In one or more embodiments, the second horizontal power line PL2b may be electrically connected to a partial configuration of the display element layer DPL through the second via hole VIH2 passing through the passivation layer PSV in each of the first, second, and third sub-pixel areas SPXA1, SPXA2, and SPXA3. For example, the second horizontal power line PL2b may be electrically connected to a first bridge pattern BRP1 of the display element layer DPL through the second via hole VIH2 passing through the passivation layer PSV in the first sub-pixel area SPXA1. In addition, the second horizontal power line PL2b may be electrically connected to a second bridge pattern (refer to second bridge pattern BRP2 of FIG. 7) of the display element layer DPL through the second via hole VIH2 passing through the passivation layer PSV in the second sub-pixel area SPXA2. In addition, the second horizontal power line PL2b may be electrically connected a third bridge pattern (refer to third bridge pattern BRP3 of FIG. 7) of the display element layer DPL through the second via hole VIH2 passing through the passivation layer PSV in the third sub-pixel area SPXA3.

The initialization power line IPL may extend in the second direction DR2 in the third sub-pixel area SPXA3, and may be positioned between the data line DL and the first vertical power line PL1a. The initialization power line IPL may be the first conductive layer. The voltage of the initialization power may be applied to the initialization power line IPL during a driving period (e.g., predetermined driving period). Accordingly, the voltage of the initialization power may be supplied to each of the first, second, and third sub-pixels SPXL1, SPXL2, and SPXL3. In one or more embodiments, the initialization power line IPL may be utilized as a sensing line SEN for detecting a characteristic of each sub-pixel from the third transistor T3 of each of the first, second, and third sub-pixels SPXL1, SPXL2, and SPXL3 during a driving period (e.g., predetermined driving period).

The first pixel circuit PXC1, the second pixel circuit PXC2, and the third pixel circuit PXC3 may have substantially similar or identical structures. Hereinafter, the first pixel circuit PXC1 among the first to third pixel circuits PXC1, PXC2, and PXC3 is described as a representative, and the second and third pixel circuits PXC2 and PXC3 are briefly described.

The first pixel circuit PXC1 may include a first transistor T1, a second transistor T2, a third transistor T3, and a storage capacitor Cst.

The first transistor T1 may include a first gate electrode GE1, a first semiconductor pattern SCP1, a first source electrode SE1, a first drain electrode DE1, and a lower metal pattern BML.

The first gate electrode GE1 may be configured of the second conductive layer, and may be provided in an island shape (or an isolated shape) in the first sub-pixel area SPXA1. The first gate electrode GE1 may be electrically connected to the second source electrode SE2 of the second transistor T2 through a corresponding contact hole CH.

The first semiconductor pattern SCP1 may include a channel area overlapping the first gate electrode GE1. In addition, the first semiconductor pattern SCP1 may include a first contact area and a second contact area positioned on both sides of the channel area. The first semiconductor pattern SCP1 may be a semiconductor layer formed of polysilicon, amorphous silicon, an oxide semiconductor, or the like. The channel area may be a semiconductor layer that is not doped with an impurity, and the first and second contact areas may be a semiconductor layer doped with an impurity.

The first semiconductor pattern SCP1 may be located between the buffer layer BFL and the gate insulating layer GI. For example, the first semiconductor pattern SCP1 may be located on the buffer layer BFL and may be surrounded by the gate insulating layer GI.

The first source electrode SE1 may be configured of the third conductive layer, and may be provided in an island shape to overlap the first gate electrode GE1 in the first sub-pixel area SPXA1. The first source electrode SE1 may be electrically connected to the first contact area of the first semiconductor pattern SCP1 through a corresponding contact hole CH. In addition, the first source electrode SE1 may be electrically connected to the lower metal pattern BML through a corresponding contact hole CH.

The lower metal pattern BML may be configured of the first conductive layer, and may be provided in an island shape to overlap the first gate electrode GE1 and the first source electrode SE1 in the first sub-pixel area SPXA1. When the lower metal pattern BML is electrically connected to the first source electrode SE1 through the corresponding contact hole CH, a driving range of a voltage (e.g., predetermined voltage) supplied to the first gate electrode GE1 may be widened. In addition, as the lower metal pattern BML is electrically connected to the first transistor T1, the likelihood of floating of the lower metal pattern BML may be reduced or prevented.

The first drain electrode DE1 may be configured of the first conductive layer, and may be electrically connected to the second contact area of the first semiconductor pattern SCP1 through a corresponding contact hole CH. In addition, the first drain electrode DE1 may be electrically connected to the first horizontal power line PL1b through a corresponding contact hole CH.

The second transistor T2 may include a second gate electrode GE2, a second semiconductor pattern SCP2, a second source electrode SE2, and a second drain electrode DE2.

The second gate electrode GE2 may be spaced apart from the first gate electrode GE1 in the first sub-pixel area SPXA1, and may be provided in an island shape. The second gate electrode GE2 may be the second conductive layer, and may be electrically connected to the second scan line SLb through a corresponding contact hole CH to receive a signal (e.g., predetermined signal, for example, the scan signal).

The second semiconductor pattern SCP2 may include a channel area overlapping the second gate electrode GE2. In addition, the second semiconductor pattern SCP2 may include a first contact area and a second contact area positioned on both sides of the channel area. The second semiconductor pattern SCP2 may be a semiconductor layer formed of polysilicon, amorphous silicon, an oxide semiconductor, or the like. The channel area may be a semiconductor layer that is not doped with an impurity, and the first and second contact areas may be a semiconductor layer doped with an impurity.

The second semiconductor pattern SCP2 may be located in the same layer as the first semiconductor pattern SCP1. For example, the second semiconductor pattern SCP2 may be located between the buffer layer BFL and the gate insulating layer GI.

The second source electrode SE2 may be configured of the third conductive layer and may overlap the first gate electrode GE1 of the first transistor T1. The second source electrode SE2 may be electrically connected to the first contact area of the second semiconductor pattern SCP2 through a corresponding contact hole CH. In addition, the second source electrode SE2 may be electrically connected to the first gate electrode GE1 through a corresponding contact hole CH.

The second drain electrode DE2 may be configured of the third conductive layer and may overlap the data line DL. The second drain electrode DE2 may be electrically connected to the second contact area of the second semiconductor pattern SCP2 through a corresponding contact hole CH. In addition, the second drain electrode DE2 may be electrically connected to the data line DL through a corresponding contact hole CH.

The third transistor T3 may include a third gate electrode GE3, a third semiconductor pattern SCP3, a third source electrode SE3, and a third drain electrode DE3.

The third gate electrode GE3 may be provided integrally with the second gate electrode GE2, and may be electrically connected to the second scan line SLb through a corresponding contact hole CH to receive a signal (e.g., a predetermined signal, for example, the control signal).

The third semiconductor pattern SCP3 may include a channel area overlapping the third gate electrode GE3. In addition, the third semiconductor pattern SCP3 may include a first contact area and a second contact area positioned on both sides of the channel area. The third semiconductor pattern SCP3 may be a semiconductor layer formed of polysilicon, amorphous silicon, an oxide semiconductor, or the like. The channel area may be a semiconductor layer that is not doped with an impurity, and the first and second contact areas may be a semiconductor layer doped with an impurity.

The third semiconductor pattern SCP3 may be located in the same layer as the first and second semiconductor patterns SCP1 and SCP2. For example, the third semiconductor pattern SCP3 may be located between the buffer layer BFL and the gate insulating layer GI.

The third source electrode SE3 may be electrically connected to the first contact area of the third semiconductor pattern SCP3 through a corresponding contact hole CH. In addition, the third source electrode SE3 may be electrically connected to the lower metal pattern BML through a corresponding contact hole CH. In one or more embodiments, the third source electrode SE3 may be configured of the third conductive layer and may be provided integrally with the first source electrode SE1.

The third drain electrode DE3 may be configured of the first conductive layer and may be electrically connected to the second contact area of the third semiconductor pattern SCP3 through a corresponding contact hole CH. In addition, the third drain electrode DE3 may be electrically connected to a conductive pattern CP through a corresponding contact hole CH.

The conductive pattern CP may extend in the first direction DR1 and may be commonly provided to the first, second, and third sub-pixel areas SPXA1, SPXA2, and SPXA3. The conductive pattern CP may be configured of the third conductive layer, and may be electrically connected to the initialization power line IPL through a corresponding contact hole CH. In addition, the conductive pattern CP may be electrically connected to the third drain electrode DE3 of the third transistor T3 of each of the first, second, and third pixel circuits PXC1, PXC2, and PXC3.

The storage capacitor Cst may include a first storage electrode LE (or a lower electrode) and a second storage electrode UE (or an upper electrode). The first storage electrode LE may be provided integrally with the first gate electrode GE1. The second storage electrode UE may be located to overlap the first storage electrode LE in a plan view. The second storage electrode UE may be configured of the third conductive layer, and may be formed integrally with the first and third source electrodes SE1 and SE3.

The second storage electrode UE, the first source electrode SE1, and the third source electrode SE3 may be electrically connected to the lower metal pattern BML through a corresponding contact hole CH.

Each of the first, second, and third pixel circuits PXC1, PXC2, and PXC3 may be covered by the passivation layer PSV.

The passivation layer PSV may include a plurality of via holes positioned in the pixel area PXA in which each pixel PXL is located. For example, the passivation layer PSV may include the first via hole VIH1, the second via hole VIH2, and the third via hole VIH3.

The first via hole VIH1 may be positioned in each of the first, second, and third sub-pixel areas SPXA1, SPXA2, and SPXA3, and may expose one area of the second storage electrode UE in a corresponding sub-pixel area. In one or more embodiments, one first via hole VIH1 may be positioned in each of the first, second, and third sub-pixel areas SPXA1, SPXA2, and SPXA3, but the disclosure is not limited thereto.

The second via hole VIH2 may be positioned in each of the first, second, and third sub-pixel areas SPXA1, SPXA2, and SPXA3, and may expose one area of the second horizontal power line PL2b in a corresponding sub-pixel area. In one or more embodiments, one second via hole VIH2 may be positioned in each of the first, second, and third sub-pixel areas SPXA1, SPXA2, and SPXA3, but the disclosure is not limited thereto.

The third via hole VIH3 may be positioned only in the first sub-pixel area SPXA1, and may expose one area of the first horizontal power line PL1b in the first sub-pixel area SPXA1. In one or more embodiments, one third via hole VIH3 may be positioned only in the first sub-pixel area SPXA1, and the third via hole VIH3 may not be positioned in each of the second and third sub-pixel areas SPXA2 and SPXA3.

The display element layer DPL including the light-emitting element LD described with reference to FIGS. 1 and 2 may be located on the pixel circuit layer PCL of each pixel PXL, and a partial configuration of the display element layer DPL may be electrically connected to a partial configuration of the pixel circuit layer PCL through a corresponding via hole. For example, the second storage electrode UE of each of the first, second, and third sub-pixels SPXL1, SPXL2, and SPXL3 may be electrically connected to the first electrode (refer to first electrode PE1 of FIG. 7), or the first pixel electrode, of the display element layer DPL through the corresponding first via hole VIH1. In addition, the second horizontal power line PL2b commonly provided to the first, second, and third sub-pixels SPXL1, SPXL2, and SPXL3 may be electrically connected to a bridge pattern of the display element layer DPL through the corresponding second via hole VIH2. For example, in the first sub-pixel SPXL1, the second horizontal power line PL2b may be electrically connected to the first bridge pattern BRP1 of the display element layer DPL through the corresponding second via hole VIH2. The first horizontal power line PL1b commonly provided to the first, second, and third sub-pixels SPXL1, SPXL2, and SPXL3 may be electrically connected to the first connection line CNL1 of the display element layer DPL through the third via hole VIH3 positioned in the first sub-pixel area SPXA1.

A detailed description of an electrical connection relationship between the pixel circuit layer PCL and the display element layer DPL is described later with reference to FIGS. 7 to 13.

Hereinafter, configurations of the display element layer DPL are described with reference to FIGS. 7 to 9.

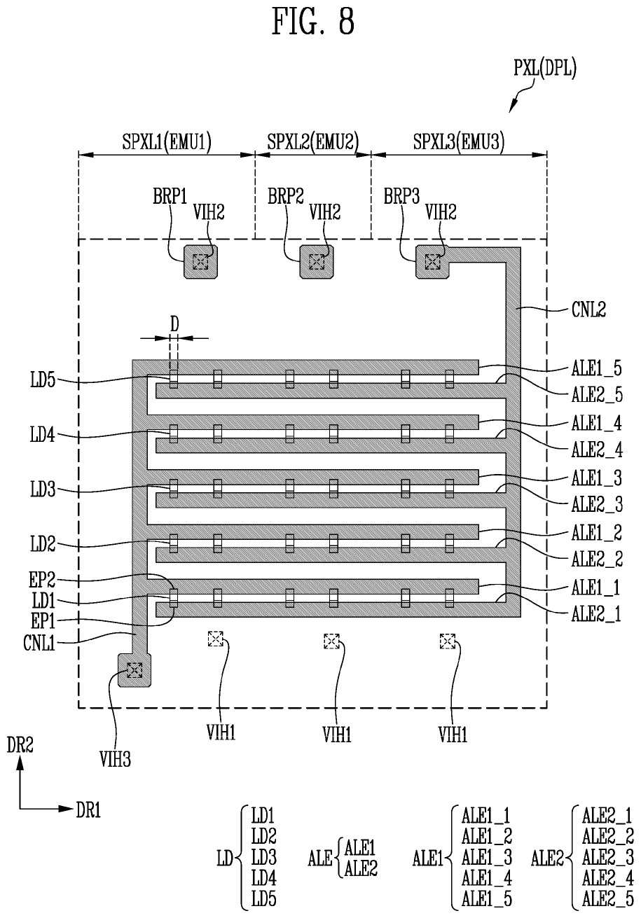

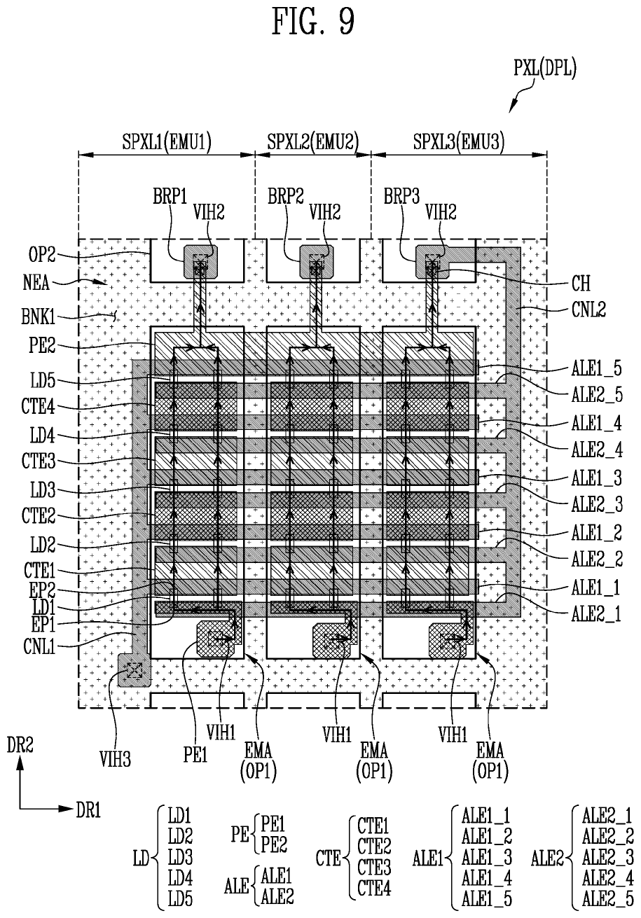

FIG. 7 is a plan view schematically illustrating the pixel area PXA including the display element layer DPL of the pixel PXL shown in FIG. 3, FIG. 8 is a plan view schematically illustrating the first and second alignment electrodes ALE1 and ALE2 and the light-emitting elements LD included in the pixel PXL of FIG. 7, and FIG. 9 is a schematic plan view illustrating a flow of a driving current flowing through the light-emitting unit EMU of the pixel PXL shown in FIG. 7.

For example, FIG. 7 schematically shows one or more embodiments of a structure of the display element layer DPL based on the pixel area PXA in which the pixel PXL of FIG. 3 is located.

In FIGS. 7 to 9, for convenience of description, a horizontal direction on a plane is indicated as a first direction DR1, and a vertical direction on the plane is indicated as a second direction DR2.

Referring to FIGS. 1 to 9, the display element layer DPL of the pixel PXL may include light-emitting units EMU1, EMU2, and EMU3 located in the pixel area PXA. For example, the display element layer DPL may include a first light-emitting unit EMU1, a second light-emitting unit EMU2, and a third light-emitting unit EMU3.

Each of the first, second, and third light-emitting units EMU1, EMU2, and EMU3 may include light-emitting elements LD electrically connected to a corresponding pixel circuit to emit light, and electrodes (or electrode patterns) electrically connected to the light-emitting elements LD. For example, the first light-emitting unit EMU1 may include the light-emitting elements LD electrically connected to the first pixel circuit PXC1, and electrodes electrically connected to the light-emitting elements LD. The second light-emitting unit EMU2 may include the light-emitting elements LD electrically connected to second pixel circuit PXC2, and electrodes electrically connected to the light-emitting elements LD. The third light-emitting unit EMU3 may include the light-emitting elements LD electrically connected to the third pixel circuit PXC3 and electrodes electrically connected to the light-emitting elements LD. The first pixel circuit PXC1 and the first light-emitting unit EMU1 may configure the first sub-pixel SPXL1, the second pixel circuit PXC2 and the second light-emitting unit EMU2 may configure the second sub-pixel SPXL2, and the third pixel circuit PXC3 and the third light-emitting unit EMU3 may configure the third sub-pixel SPXL3.

Each of the first, second, and third sub-pixels SPXL1, SPXL2, and SPXL3 may include an emission area EMA and a non-emission area NEA surrounding at least one side of the emission area EMA.

The display element layer DPL may include a first bank BNK1 positioned in the non-emission area NEA.

The first bank BNK1 may be a pixel defining layer as a structure defining (or partitioning) the emission area of each of adjacent sub-pixels. For example, the first bank BNK1 may be a structure defining the emission area EMA of each of the first, second, and third sub-pixels SPXL1, SPXL2, and SPXL3. In a process of supplying (or inputting) the light-emitting elements LD to each of the first, second, and third sub-pixels SPXL1, SPXL2, and SPXL3, the first bank BNK1 may be a pixel defining layer or a dam structure defining a supply position of the light-emitting elements LD. For example, as the emission area EMA of each of the first, second, and third sub-pixels SPXL1, SPXL2, and SPXL3 are partitioned (or defined) by the first bank BNK1, a mixed solution (e.g., an ink) including a desired amount and/or type of the light-emitting element LD may be supplied (or input) to the corresponding emission area EMA.

According to one or more embodiments, the first bank BNK1 may be configured to include at least one light blocking material and/or reflective material (or scattering material) to reduce or prevent a light leakage defect in which light (or rays) leaks between adjacent sub-pixels. According to one or more embodiments, the first bank BNK1 may include a transparent material (or substance). The transparent material may include, for example, polyamides resin, polyimides resin, and the like, but is not limited thereto. According to one or more other embodiments, a reflective material layer may be separately provided and/or formed on the first bank BNK1 to further improve efficiency of light emitted from each of the first, second, and third sub-pixels SPXL1, SPXL2, and SPXL3.

The first bank BNK1 may include at least one or more openings OP1 and OP2 exposing some configurations of the display element layer DPL. For example, the first bank BNK1 may include a first opening OP1 and a second opening OP2 exposing configurations positioned under the first bank BNK1 in the display element layer DPL. In one or more embodiments, the emission area EMA of each of the first, second, and third sub-pixels SPXL1, SPXL2, and SPXL3 may correspond to the first opening OP1 of the first bank BNK1. The second opening OP2 of the first bank BNK1 may be positioned in the non-emission area NEA.

The second opening OP2 of the first bank BNK1 may be spaced apart from the first opening OP1, and may be positioned adjacent to one side (e.g., an upper side) of a corresponding sub-pixel (or a corresponding sub-pixel area). In one or more embodiments, the second via hole VIH2 may be positioned in the second opening OP2 of the first bank BNK1. One areas of the second horizontal power line PL2b of each pixel PXL may be exposed through the second via hole VIH2 in the second opening OP2.

The display element layer DPL may include an electrode PE (or a pixel electrode) provided in the emission area EMA of each of the first, second, and third sub-pixels SPXL1, SPXL2, and SPXL3, the light-emitting elements LD, and an alignment electrode ALE corresponding to the electrode PE. For example, the first and second electrodes PE1 and PE2, the light-emitting elements LD, and the first and second alignment electrodes ALE1 and ALE2 may be located in the emission area EMA of each sub-pixel. In addition, the first, second, third, and fourth intermediate electrodes CTE1, CTE2, CTE3, and CTE4 may be located in the emission area EMA of each sub-pixel. The number, shape, size, arrangement structure, and the like of each of the electrodes PE and/or the alignment electrodes ALE may be variously changed according to a structure of the first, second, and third sub-pixels SPXL1, SPXL2, SPXL3 (for example, the first, second, and third light-emitting units EMU1, EMU2, and EMU3).

The first light-emitting unit EMU1, the second light-emitting unit EMU2, and the third light-emitting unit EMU3 may have substantially similar or identical structures. Hereinafter, configurations of the first light-emitting unit EMU1 are described based on the first sub-pixel SPXL1 including the first light-emitting unit EMU1.

In one or more embodiments, the alignment electrodes ALE, the light-emitting elements LD, and the electrodes PE may be sequentially provided based on one surface of the substrate SUB on which the first sub-pixel SPXL1 is provided (or positioned), but the disclosure is not limited thereto. According to one or more embodiments, a position and a formation order of electrode patterns configuring the first sub-pixel SPXL1 (or the first light-emitting unit EMU1) may be variously changed.

The alignment electrodes ALE may include the first alignment electrode ALE1 and the second alignment electrode ALE2 arranged to be spaced apart from each other (e.g., with respect to the second direction DR2). In one or more embodiments, the first alignment electrode ALE1 and the second alignment electrode ALE2, or respective portions thereof, may extend in the first direction DR1. For example, the first alignment electrode ALE1 and the second alignment electrode ALE2 may extend in the first direction DR1, which is the direction crossing an extension direction of a partial configuration of the pixel circuit layer PCL, for example, the data line Dj (e.g., the second direction DR2). That is, the data line Dj may extend in the direction (e.g., the second direction DR2) crossing an extension direction (e.g., the first direction DR1) of the first and second alignment electrodes ALE1 and ALE2. In addition, the first and second alignment electrodes ALE1 and ALE2 may extend in a direction (e.g., the first direction DR1) crossing a long axis direction of the first bank BNK1 (e.g., the second direction DR2) in a plan view.

A plurality of first alignment electrodes ALE1 and second alignment electrodes ALE2 may be provided. For example, the first alignment electrode ALE1 may include (1-1)-th, (1-2)-th, (1-3)-th, (1-4)-th, and (1-5)-th alignment electrodes ALE1_1, ALE1_2, ALE1_3, ALE1_4, and ALE1_5 extending in the first direction DR1. The second alignment electrode ALE2 may include (2-1)-th, (2-2)-th, (2-3)-th, (2-4)-th, and (2-5)-th alignment electrodes ALE2_1, ALE2_2, ALE2_3, ALE2_4, and ALE2_5 extending in the first direction DR1, and spaced apart from the first alignment electrode ALE1.

The first alignment electrode ALE1 and the second alignment electrode ALE2 may be alternately arranged along the second direction DR2 at least in the emission area EMA. For example, in the emission area EMA, the (2-1)-th alignment electrode ALE2_1, the (1-1)-th alignment electrode ALE1_1, the (2-2)-th alignment electrode ALE2_2, the (1-2)-th alignment electrode ALE1_2, the (2-3)-th alignment electrode ALE2_3, the (1-3)-th alignment electrode ALE1_3, the (2-4)-th alignment electrode ALE2_4, the (1-4)-th alignment electrode ALE1_4, the (2-5)-th alignment electrode ALE2_5, and the (1-5)-th alignment electrode ALE1_5 may be sequentially arranged along the second direction DR2.

In the emission area EMA, each of the first alignment electrode ALE1 and the second alignment electrode ALE2 may be spaced apart from the adjacent alignment electrode ALE along the second direction DR2. For example, the (2-1)-th alignment electrode ALE2_1 may be spaced apart from the (1-1)-th alignment electrode ALE1_1 in the second direction DR2, the (1-1)-th alignment electrode ALE1_1 may be spaced apart from the (2-1)-th and (2-2)-th alignment electrodes ALE2_1 and ALE2_2 in the second direction DR2, the (2-2)-th alignment electrode ALE2_2 may be spaced apart from the (1-1)-th and (1-2)-th alignment electrodes ALE1_1 and ALE1_2 in the second direction DR2, the (1-2)-th alignment electrode ALE1_2 may be spaced apart from the (2-2)-th and (2-3)-th alignment electrodes ALE2_2 and ALE2_3 in the second direction DR2, the (2-3)-th alignment electrode ALE2_3 may be spaced apart from the (1-2)-th and (1-3)-th alignment electrodes ALE1_2 and ALE1_3 in the second direction DR2, the (1-3)-th alignment electrode ALE1_3 may be spaced apart from the (2-3)-th and (2-4)-th alignment electrodes ALE2_3 and ALE2_4 in the second direction DR2, the (2-4)-th alignment electrode ALE2_4 may be spaced apart from the (1-3)-th and (1-4)-th alignment electrodes ALE1_3 and ALE1_4 in the second direction DR2, the (1-4)-th alignment electrode ALE1_4 may be spaced apart from the (2-4)-th and (2-5)-th alignment electrodes ALE2_4 and the ALE2_5 in the second direction DR2, and the (2-5)-th alignment electrode ALE2_5 may be spaced apart from the (1-4)-th and (1-5)-th alignment electrodes ALE1_4 and ALE1_5 in the second direction DR2.

The first alignment electrode ALE1 and the second alignment electrode ALE2 may be provided in a bar shape having respective portions extending in the first direction DR1 and having a constant width in the second direction DR2.

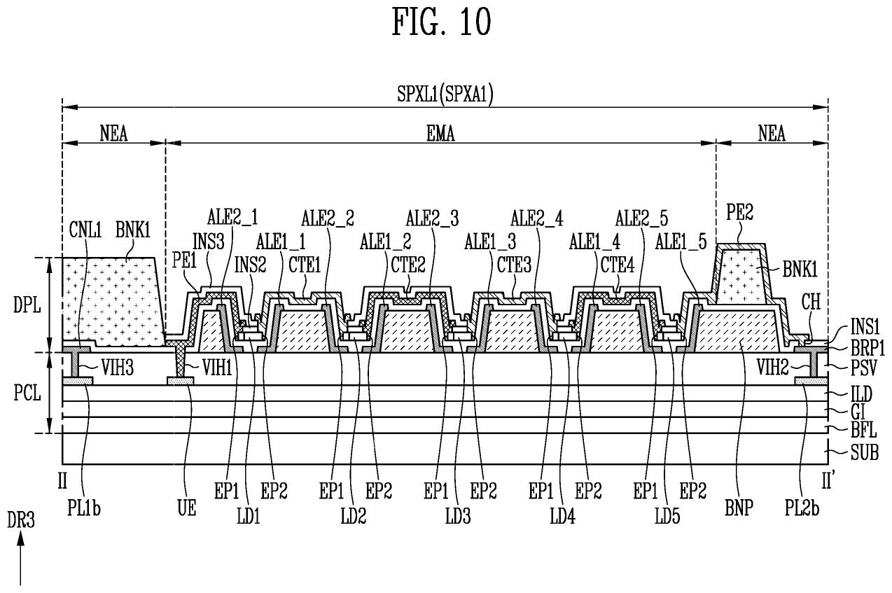

A bank pattern for changing a surface profile (or a shape) of the first and second alignment electrodes ALE1 and ALE2 to guide light emitted from light-emitting elements LD in an image display direction of the display device may be positioned under the above-described first and second alignment electrodes ALE1 and ALE2. The bank pattern may be a support member supporting each of the first and second alignment electrodes ALE1 and ALE2. Such a bank pattern is described later with reference to FIGS. 10 to 13.

The first alignment electrode ALE1 and the second alignment electrode ALE2 may extend to the emission area EMA of each of the second and third sub-pixels SPXL2 and SPXL3 from the emission area EMA of the first sub-pixel SPXL1 along the first direction DR1. For example, each of the first and second alignment electrodes ALE1 and ALE2 may be commonly provided to the emission area EMA of each of the first, second, and third sub-pixels SPXL1, SPXL2, and SPXL3.

In one or more embodiments, each of the (1-1)-th alignment electrode ALE1_1, the (1-2)-th alignment electrode ALE1_2, the (1-3)-th alignment electrode ALE1_3, the (1-4)-th alignment electrode ALE1_4, and the (1-5)-th alignment electrode ALE1_5 may include respective ends with respect to the first direction DR1. For example, each of the (1-1)-th alignment electrode ALE1_1, the (1-2)-th alignment electrode ALE1_2, the (1-3)-th alignment electrode ALE1_3, the (1-4)-th alignment electrode ALE1_4, and the (1-5)-th alignment electrode ALE1_5 may each include one end positioned in the non-emission area NEA of the first sub-pixel SPXL1, and another end positioned in the non-emission area NEA of the third sub-pixel SPXL3.

The first alignment electrode ALE1 may be connected to the first connection line CNL1 positioned in the non-emission area NEA of the first sub-pixel SPXL1. For example, the one end of each of the (1-1)-th alignment electrode ALE1_1, the (1-2)-th alignment electrode ALE1_2, the (1-3)-th alignment electrode ALE1_3, the (1-4)-th alignment electrode ALE1_4, and the (1-5)-th alignment electrode ALE1_5 may be connected to the first connection line CNL1. The first connection line CNL1 may extend in the second direction DR2 crossing an extension direction (e.g., the first direction DR1) of the first alignment electrode ALE1.

In one or more embodiments, the first alignment electrode ALE1 and the first connection line CNL1 may be integrally formed. For example, the (1-1)-th alignment electrode ALE1_1, the (1-2)-th alignment electrode ALE1_2, the (1-3)-th alignment electrode ALE1_3, the (1-4)-th alignment electrode ALE1_4, and the (1-5)-th alignment electrode ALE1_5 may be integrally formed with the first connection line CNL1. The one end of each of the (1-1)-th alignment electrode ALE1_1, the (1-2)-th alignment electrode ALE1_2, the (1-3)-th alignment electrode ALE1_3, the (1-4)-th alignment electrode ALE1_4, and the (1-5)-th alignment electrode ALE1_5 may be branched from respective areas of the first connection line CNL1, and may extend to the emission area EMA of each of the first, second, and third sub-pixels SPXL1, SPXL2, and SPXL3.

The first connection line CNL1 may be electrically connected to the first horizontal power line PL1b positioned in the pixel circuit layer PCL of the first sub-pixel SPXL1 through the third via hole VIH3. The first connection line CNL1 and the first alignment electrode ALE1 electrically connected to the first horizontal power line PL1b through the third via hole VIH3 may be utilized as the first alignment line in an operation of aligning the light-emitting elements LD to the emission areas EMA of each of the first, second, and third sub-pixels SPXL1, SPXL2, and SPXL3. A first alignment signal (or a first alignment voltage) may be applied to the first alignment electrode ALE1. The third via hole VIH3 may be formed by removing one area of an insulating layer positioned between the first connection line CNL1 and the first horizontal power line PL1b, for example, the passivation layer PSV.

In one or more embodiments, each of the (2-1)-th alignment electrode ALE2_1, the (2-2)-th alignment electrode ALE2_2, the (2-3)-th alignment electrode ALE2_3, the (2-4)-th alignment electrode ALE2_4, and the (2-5)-th alignment electrode ALE2_5 may include respective ends facing each other in the first direction DR1. For example, each of the (2-1)-th alignment electrode ALE2_1, the (2-2)-th alignment electrode ALE2_2, the (2-3)-th alignment electrode ALE2_3, the (2-4)-th alignment electrode ALE2_4, and the (2-5)-th alignment electrode ALE2_5 may include one end positioned in the non-emission area NEA of the third sub-pixel SPXL3, and another end positioned in the non-emission area NEA of the first sub-pixel SPXL1.

The second alignment electrode ALE2 may be connected to a second connection line CNL2 positioned in the non-emission area NEA of the third sub-pixel SPXL3. For example, the one end of each of the (2-1)-th alignment electrode ALE2_1, the (2-2)-th alignment electrode ALE2_2, the (2-3)-th alignment electrode ALE2_3, the (2-4)-th alignment electrode ALE2_4, and the (2-5)-th alignment electrode ALE2_5 may be connected to the second connection line CNL2. The second connection line CNL2 may extend in the second direction DR2 crossing an extension direction (e.g., the first direction DR1) of the second alignment electrode ALE2.

In one or more embodiments, the second alignment electrode ALE2 and the second connection line CNL2 may be integrally formed. For example, the (2-1)-th alignment electrode ALE2_1, the (2-2)-th alignment electrode ALE2_2, the (2-3)-th alignment electrode ALE2_3, the (2-4)-th alignment electrode ALE2_4, and the (2-5)-th alignment electrode ALE2_5 may be integrally formed with the second connection line CNL2. The one end of each of the (2-1)-th alignment electrode ALE2_1, the (2-2)-th alignment electrode ALE2_2, the (2-3)-th alignment electrode ALE2_3, the (2-4)-th alignment electrode ALE2_4, and the (2-5)-th alignment electrode ALE2_5 may be branched from respective areas of the second connection line CNL2 and may extend to the emission area EMA of each of the third, second, and first sub-pixels SPXL3, SPXL2, and SPXL1 along the first direction DR1.

The second connection line CNL2 may be integrally formed with the third bridge pattern BRP3. The third bridge pattern BRP3 and the second connection line CNL2 may be electrically connected to the second horizontal power line PL2b positioned in the pixel circuit layer PCL of the third sub-pixel SPXL3 through the second via hole VIH2. The second connection line CNL2 and the second alignment electrode ALE2 electrically connected to the second horizontal power line PL2b through the second via hole VIH2 may be utilized as the second alignment line in the operation of aligning the light-emitting elements LD to the emission areas EMA of each of the third, second, and first sub-pixels SPXL3, SPXL2, and SPXL1. A second alignment signal (or a second alignment voltage) may be applied to the second alignment electrode ALE2. The second via hole VIH2 may be formed by removing one area of an insulating layer positioned between the third bridge pattern BRP3 and the second horizontal power line PL2b, for example, the passivation layer PSV. The second via hole VIH2 may be positioned in the second opening OP2 of the first bank BNK1 in the third sub-pixel SPXL3.

The second horizontal power line PL2b may be electrically connected to the second bridge pattern BRP2 through the second via hole VIH2 in the second sub-pixel SPXL2. In addition, the second horizontal power line PL2b may be electrically connected to the first bridge pattern BRP1 through the second via hole VIH2 in the first sub-pixel SPXL1.

Each of the above-described first bridge pattern BRP1, second bridge pattern BRP2, and third bridge pattern BRP3 may be electrically connected to the second electrodes PE2 of each of the first, second, and third sub-pixels SPXL1, SPXL2, and SPXL3 through a corresponding contact hole CH. The contact hole CH may be formed by removing one area of the insulating layer positioned between each of the first, second, and third bridge patterns BRP1, BRP2, and BRP3 and the second electrode PE2.

As an example, two to tens of light-emitting elements LD may be aligned and/or located in the emission area EMA (or the first sub-pixel area SPXA1) of the first sub-pixel SPXL1, but the number of the light-emitting elements LD is not limited thereto. According to one or more embodiments, the number of light-emitting elements LD arranged and/or located in the emission area EMA may be variously changed according to one or more embodiments.

Each of the light-emitting elements LD may be located between the first alignment electrode ALE1 and the second alignment electrode ALE2. In a plan view, each of the light-emitting elements LD may include a first end EP1 (e.g., one end, or a lower end) and a second end EP2 (e.g., another end, or an upper end) positioned at respective ends (e.g., facing each other) in the length direction, for example, the second direction DR2. In one or more embodiments, the second semiconductor layer (e.g., the second semiconductor layer 13 of FIG. 1) including the p-type semiconductor layer may be positioned at the first end EP1, and the first semiconductor layer (e.g., first semiconductor layer 11 of FIG. 1) including the n-type semiconductor layer may be positioned at the second end EP2. The light-emitting elements LD may be connected in parallel to each other between the first alignment electrode ALE1 and the second alignment electrode ALE2.

The light-emitting elements LD may be spaced apart from each other and may be aligned to be substantially parallel to each other. A distance at which the light-emitting elements LD are spaced apart is not particularly limited. According to one or more embodiments, a plurality of light-emitting elements LD may be located adjacent to each other to form a group, and a plurality of other light-emitting elements LD may form a group in a state in which the plurality of other light-emitting elements LD are spaced apart from each other by a distance (e.g., predetermined distance), may have non-uniform density, and may be aligned in one direction.

Each of the light-emitting elements LD may emit any one of color light and/or white light. Each of the light-emitting elements LD may be aligned between the first alignment electrode ALE1 and the second alignment electrode ALE2 so that the length direction is parallel to the second direction DR2. The light-emitting elements LD may be provided in a form in which the light-emitting elements LD are sprayed (or dispersed) in a solution (e.g., an ink) and may be input (or supplied) to the emission area EMA.

The light-emitting elements LD may be input (or supplied) to the emission area EMA through an inkjet printing method, a slit coating method, or other various methods. For example, the light-emitting elements LD may be mixed with a volatile solvent and input (or supplied) to the emission area EMA through an inkjet printing method or a slit coating method. At this time, when an alignment signal corresponding to each of the first alignment electrode ALE1 and the second alignment electrode ALE2 is applied, an electric field may be formed between the first alignment electrode ALE1 and the second alignment electrode ALE2. Accordingly, the light-emitting elements LD may be aligned between the first alignment electrode ALE1 and the second alignment electrode ALE2. The light-emitting elements LD having the length direction parallel to the second direction DR2 may be stably aligned between the first alignment electrode ALE1 and the second alignment electrode ALE2 by volatilizing, or otherwise removing the solvent in another method, after the light-emitting elements LD are aligned.

In one or more embodiments, the light-emitting elements LD may include a first light-emitting element LD1, a second light-emitting element LD2, a third light-emitting element LD3, a fourth light-emitting element LD4, and a fifth light-emitting element LD5.

The first light-emitting element LD1 may be aligned between the (2-1)-th alignment electrode ALE2_1 and the (1-1)-th alignment electrode ALE1_1 to be electrically connected to the first electrode PE1 and the first intermediate electrode CTE1. The second light-emitting element LD2 may be aligned between the (2-2)-th alignment electrode ALE2_2 and the (1-2)-th alignment electrode ALE1_2 to be electrically connected to the first intermediate electrode CTE1 and the second intermediate electrode CTE2. The third light-emitting element LD3 may be aligned between the (2-3)-th alignment electrode ALE2_3 and the (1-3)-th alignment electrode ALE1_3 to be electrically connected to the second intermediate electrode CTE2 and the third intermediate electrode CTE3. The fourth light-emitting element LD4 may be aligned between the (2-4)-th alignment electrode ALE2_4 and the (1-4)-th alignment electrode ALE1_4 to be electrically connected to the third intermediate electrode CTE3 and the fourth intermediate electrode CTE4. The fifth light-emitting element LD5 may be aligned between the (2-5)-th alignment electrode ALE2_5 and the (1-5)-th alignment electrode ALE1_5 to be electrically connected to the fourth intermediate electrode CTE4 and the second electrode PE2.

According to one or more embodiments, the light-emitting element LD may include an ineffective light source in addition to the first, second, third, fourth, and fifth light-emitting elements LD1, LD2, LD3, LD4 and LD5. The ineffective light source may be positioned in an area in which the first, second, third, fourth, and fifth light-emitting elements LD1, LD2, LD3, LD4 and LD5 are not aligned between the first alignment electrode ALE1 and the second alignment electrode ALE2. For example, the ineffective light source may be positioned between the (1-1)-th alignment electrode ALE1_1 and the (2-2)-th alignment electrode ALE2_2, between the (1-2)-th alignment electrode ALE1_2 and the (2-3)-th alignment electrode ALE2_3, between the (1-3)-th alignment electrode ALE1_3 and the (2-4)-th alignment electrode ALE2_4, and between the (1-4)-th alignment electrode ALE1_4 and the (2-5)-th alignment electrode ALE2_5. The above-described ineffective light source may be connected between the first alignment electrode ALE1 and the second alignment electrode ALE2 in a direction opposite to the first, second, third, fourth, and fifth light-emitting elements LD1, LD2, LD3, LD4, and LD5, and may maintain an inactive state even though a driving voltage (e.g., predetermined driving voltage, for example, a forward driving voltage) is applied between the first electrode PE1 and the second electrode PE2, and thus a current substantially may not flow.

In a plan view, the first light-emitting element LD1 may be positioned at a lower end of a corresponding emission area EMA, and the fifth light-emitting element LD5 may be positioned at an upper end of the corresponding emission area EMA. In a plan view, the third light-emitting element LD3 may be positioned at a midpoint of the corresponding emission area EMA. In a plan view, the second light-emitting element LD2 may be positioned in an area between the area where the first light-emitting element LD1 is positioned and the area where the third light-emitting element LD3 is positioned, and the fourth light-emitting element LD4 may be positioned in an area between the area where the third light-emitting element LD3 is positioned and the area where the fifth light-emitting element LD5 is positioned.

A plurality of first, second, third, fourth, and fifth light-emitting elements LD1, LD2, LD3, LD4, and LD5 may be provided.

The first end EP1 of each of the first light-emitting elements LD1 may be electrically connected to the first electrode PE1, and the second end EP2 of each of the first light-emitting elements LD1 may be electrically connected to the first intermediate electrode CTE1. The first end EP1 of each of the second light-emitting elements LD2 may be electrically connected to the first intermediate electrode CTE1, and the second end EP2 of each of the second light-emitting elements LD2 may be electrically connected to the second intermediate electrode CTE2. The first end EP1 of each of the third light-emitting elements LD3 may be electrically connected to the second intermediate electrode CTE2, and the second end EP2 of each of the third light-emitting elements LD3 may be electrically connected to the third intermediate electrode CTE3. The first end EP1 of each of the fourth light-emitting elements LD4 may be electrically connected to the third intermediate electrode CTE3, and the second end EP2 of each of the fourth light-emitting elements LD4 may be electrically connected to the fourth intermediate electrode CTE4. The first end EP1 of each of the fifth light-emitting elements LD5 may be electrically connected to the fourth intermediate electrode CTE4, and the second end EP2 of each of the fifth light-emitting elements LD5 may be electrically connected to the second electrode PE2.

The plurality of first light-emitting elements LD1 may be electrically connected to each other in parallel between the first electrode PE1 and the first intermediate electrode CTE1, the plurality of second light-emitting elements LD2 may be electrically connected to each other in parallel between the first intermediate electrode CTE1 and the second intermediate electrode CTE2, the plurality of third light-emitting elements LD3 may be electrically connected to each other in parallel between the second intermediate electrode CTE2 and the third intermediate electrode CTE3, the plurality of fourth light-emitting elements LD4 may be electrically connected to each other in parallel between the third intermediate electrode CTE3 and the fourth intermediate electrode CTE4, and the plurality of fifth light-emitting elements may be electrically connected to each other in parallel between the fourth intermediate electrode CTE4 and the second electrode PE2.

According to one or more embodiments, each of the first, second, third, fourth, and fifth light-emitting elements LD1, LD2, LD3, LD4, and LD5 may be a light-emitting diode of an ultra-small of a small size, for example, a nano scale (or nano meter) to a micro scale (or micro meter), using a material of an inorganic crystal structure. For example, each of the first, second, third, fourth, and fifth light-emitting elements LD1, LD2, LD3, LD4 and LD5 may be the light-emitting element LD described with reference to FIGS. 1 and 2.

The electrode PE (or the pixel electrode) and the intermediate electrode CTE may be provided in at least the emission area EMA, and may be provided at a position corresponding to each at least one alignment electrode ALE and the light-emitting elements LD. For example, each electrode PE and each intermediate electrode CTE may be formed on corresponding light-emitting elements LD to overlap each alignment electrode ALE and the corresponding light-emitting elements LD, and may be electrically connected to at least the light-emitting elements LD.

The first electrode PE1 (or the first pixel electrode) may be formed on the (2-1)-th alignment electrode ALE2_1 and on the first end EP1 of each of the first light-emitting elements LD1 to be electrically connected to the first end EP1 of each of the first light-emitting elements LD1. The first electrode PE1 may be provided in an island shape (or an isolated shape) in a corresponding emission area EMA. The first electrode PE1 of the first sub-pixel SPXL1 may be electrically separated from the first electrode PE1 of an adjacent sub-pixel. For example, the first electrode PE1 of the first sub-pixel SPXL1 may be provided in an island shape, which is spaced apart from the first electrode PE1 of each of the second and third sub-pixels SPXL2 and SPXL3 to be electrically separated from (or insulated from) the first electrode PE1 of each of the second and third sub-pixels SPXL2 and SPXL3.

The second electrode PE2 (or the second pixel electrode) may be formed on the (1-5)-th alignment electrode ALE1_5 and the second end EP2 of each of the fifth light-emitting elements LD5 to be electrically connected to the second end EP2 of each of the fifth light-emitting elements LD5. The second electrode PE2 may be electrically connected to the first, second, third, and fourth light-emitting elements LD1, LD2, LD3 and LD4 via at least one intermediate electrode CTE and/or the light-emitting elements LD. The second electrode PE2 may have a shape extending in the first direction DR1. The second electrode PE2 of the first sub-pixel SPXL1 may be connected to the second electrode PE2 of the sub-pixel adjacent in the first direction DR1. For example, the second electrode PE2 of the first sub-pixel SPXL1 may be connected to the second electrode PE2 of each of the second and third sub-pixels SPXL2 and SPXL3.

The intermediate electrode CTE may include the first intermediate electrode CTE1, the second intermediate electrode CTE2, the third intermediate electrode CTE3, and the fourth intermediate electrode CTE4 spaced apart from each other in the second direction DR2.

The first intermediate electrode CTE1 may be formed on the (1-1)-th alignment electrode ALE1_1 and the second end EP2 of each of the first light-emitting elements LD1 to be electrically connected to the second end EP2 of each of the first light-emitting elements LD1. In addition, the first intermediate electrode CTE1 may be formed on the (2-2)-th second alignment electrode ALE2_2 and the first end EP1 of each of the second light-emitting elements LD2 to be electrically connected to the first end EP1 of each of the second light-emitting elements LD2. The above-described first intermediate electrode CTE1 may be a first connection member electrically connecting the first series stage SET1 (or the first light-emitting elements LD1) and the second series stage SET2 (or the second light-emitting elements LD2).

The second intermediate electrode CTE2 may be formed on the (1-2)-th alignment electrode ALE1_2 and the second end EP2 of each of the second light-emitting elements LD2 to be electrically connected to the second end EP2 of each of the second light-emitting elements LD2. In addition, the second intermediate electrode CTE2 may be formed on the (2-3)-th alignment electrode ALE2_3 and the first end EP1 of each of the third light-emitting elements LD3 to be electrically connected to the first end EP1 of each of the third light-emitting elements LD3. The above-described second intermediate electrode CTE2 may be a second connection member electrically connecting the second series stage SET2 (or the second light-emitting elements LD2) and the third series stage SET3 (or the third light-emitting elements LD3).

The third intermediate electrode CTE3 may be formed on the (1-3)-th alignment electrodes ALE1_3 and the second end EP2 of each of the third light-emitting elements LD3 to be electrically connected to the second end EP2 of each of the third light-emitting elements LD3. In addition, the third intermediate electrode CTE3 may be formed on the (2-4)-th alignment electrode ALE2_4 and the first end EP1 of each of the fourth light-emitting elements LD4 to be electrically connected to the first end EP1 of each of the fourth light-emitting elements LD4. The above-described third intermediate electrode CTE3 may be a third connection member electrically connecting the third series stage SET3 (or the third light-emitting elements LD3) and the fourth series stage SET4 (or the fourth light-emitting elements LD4).

The fourth intermediate electrode CTE4 may be formed on the (1-4)-th alignment electrodes ALE1_4 and the second end EP2 of each of the fourth light-emitting elements LD4 to be electrically connected to the second end EP2 of each of the fourth light-emitting elements LD4. In addition, the fourth intermediate electrode CTE4 may be formed on the (2-5)-th alignment electrode ALE2_5 and the first end EP1 of each of the fifth light-emitting elements LD5 to be electrically connected to the first end EP1 of each of the fifth light-emitting elements LD5. The above-described fourth intermediate electrode CTE4 may be a fourth connection member electrically connecting the fourth series stage SET4 (or the fourth light-emitting elements LD4) and the fifth series stage SET5 (or the fifth light-emitting elements LD5).

Each of the first, second, third, and fourth intermediate electrodes CTE1, CTE2, CTE3, and CTE4 may be provided in a quadrangular shape in the corresponding emission area EMA, but is not limited thereto. For example, the first intermediate electrode CTE1 of the first sub-pixel SPXL1 may be provided in an island shape in the corresponding emission area EMA to be electrically separated from (or insulated from) the first intermediate electrode CTE1 of each of the second and third sub-pixels SPXL2 and SPXL3. The second intermediate electrode CTE2 of the first sub-pixel SPXL1 may be provided in an island shape in the corresponding emission area EMA to be electrically separated from (or insulated from) the second intermediate electrode CTE2 of each of the second and third sub-pixels SPXL2 and SPXL3. The third intermediate electrode CTE3 of the first sub-pixel SPXL1 may be provided in an island shape in the corresponding emission area EMA to be electrically separated from (or insulated from) the third intermediate electrode CTE3 of each of the second and third sub-pixels SPXL2 and SPXL3. The fourth intermediate electrode CTE4 of the first sub-pixel SPXL1 may be provided in an island shape in the corresponding emission area EMA to be electrically separated from (or insulated from) the fourth intermediate electrode CTE4 of each of the second and third sub-pixels SPXL2 and SPXL3.

The first electrode PE1 and the first intermediate electrode CTE1 may configure the first series stage SET1 of the first light-emitting unit EMU1 together with the first light-emitting elements LD1 connected in parallel therebetween, the first intermediate electrode CTE1 and the second intermediate electrode CTE2 may configure the second series stage SET2 of the first light-emitting unit EMU1 together with the second light-emitting elements LD2 connected in parallel therebetween, the second intermediate electrode CTE2 and the third intermediate electrode CTE3 may configure the third series stage SET3 of the first light-emitting unit EMU1 together with the third light-emitting elements LD3 connected in parallel therebetween, the third intermediate electrode CTE3 and the fourth intermediate electrode CTE4 may configure the fourth series stage SET4 of the first light-emitting unit EMU1 together with the fourth light-emitting elements LD4 connected in parallel therebetween, and the fourth intermediate electrode CTE4 and the second electrode PE2 may configure the fifth series stage SET5 of the first light-emitting unit EMU1 together with the fifth light-emitting elements LD5 connected in parallel therebetween. The first electrode PE1 may be an anode of the first light-emitting unit EMU1, and the second electrode PE2 may be a cathode of the first light-emitting unit EMU1.

In one or more embodiments, the first electrode PE1 may be electrically connected to a partial configuration of the first pixel circuit PXC of the first sub-pixel SPXL through the first via hole VIH1. For example, the first electrode PE1 may be electrically connected to the second storage electrode UE (or the upper electrode) of the storage capacitor Cst of the first pixel circuit PXC1 through the first via hole VIH1. The second electrode PE2 may be electrically connected to the first bridge pattern BRP1 through a corresponding contact hole CH. The first bridge pattern BRP1 may be electrically connected to a partial configuration connected to the first pixel circuit PXC through the second via hole VIH2. For example, the second electrode PE2 may be electrically connected to the second horizontal power line PL2b through the first bridge pattern BRP1 and the second via hole VIH2.

The second electrode PE2 provided in the second sub-pixel SPXL2 may be electrically connected to the second bridge pattern BRP2 through a corresponding contact hole CH. The second bridge pattern BRP2 may be electrically connected to the second horizontal power line PL2b connected to the second pixel circuit PXC2 of the second sub-pixel SPXL2 through the second via hole VIH2. The second electrode PE2 provided in the third sub-pixel SPXL3 may be electrically connected to the third bridge pattern BRP3 through a corresponding contact hole CH. The third bridge pattern BRP3 may be electrically connected to the second horizontal power line PL2b connected to the third pixel circuit PXC3 of the third sub-pixel SPXL3.

Each of the first, second, and third bridge patterns BRP1, BRP2, and BRP3 may be positioned in the second opening OP2 of the first bank BNK1 in a corresponding sub-pixel area. For example, the first bridge pattern BRP1 may be positioned in the second opening OP2 of the first bank BNK1 in the first sub-pixel area SPXA1, the second bridge pattern BRP2 may be positioned in the second opening OP2 of the first bank BNK1 in the second sub-pixel area SPXA2, and the third bridge pattern BRP3 may be positioned in the second opening OP2 of the first bank BNK1 in the third sub-pixel area SPXA3. The first, second, and third bridge patterns BRP1, BRP2, and BRP3 may be formed in the same process as the first and second alignment electrodes ALE1 and ALE2. The third bridge pattern BRP3 may be formed integrally with the second connection line CNL2.

The above-described first electrode PE1 and second electrode PE2 may be driving electrodes for driving the light-emitting elements LD.

During each frame period, in the first sub-pixel SPXL1, a driving current may flow from the first electrode PE1 to the second electrode PE2 through the first light-emitting element LD1, the first intermediate electrode CTE1, the second light-emitting element LD2, the second intermediate electrode CTE2, the third light-emitting element LD3, the third intermediate electrode CTE3, the fourth light-emitting element LD4, the fourth intermediate electrode CTE4, and the fifth light-emitting element LD5.

When it is assumed that the driving current flows from the first power line PL1 to the second power line PL2 by the first transistor T1 included in the first pixel circuit PXC1, the driving current may be input to the first light-emitting unit EMU1 through the first via hole VIH1.

For example, the driving current is supplied to the first electrode PE1 through the first via hole VIH1, and the driving current flows to the first intermediate electrode CTE1 via the first light-emitting elements LD1 through the first electrode PE1. Accordingly, in the first series stage SET1, the first light-emitting elements LD1 may emit light with a luminance corresponding to a distributed current.

The driving current flowing to the first intermediate electrode CTE1 flows to the second intermediate electrode CTE2 via the second light-emitting elements LD2. Accordingly, in the second series stage SET2, the second light-emitting elements LD2 may emit light with a luminance corresponding to a distributed current.

The driving current flowing to the second intermediate electrode CTE2 flows to the third intermediate electrode CTE3 via the third light-emitting elements LD3. Accordingly, in the third series stage SET3, the third light-emitting elements LD3 may emit light with a luminance corresponding to a distributed current.

The driving current flowing to the third intermediate electrode CTE3 flows to the fourth intermediate electrode CTE4 via the fourth light-emitting elements LD4. Accordingly, in the fourth series stage SET4, the fourth light-emitting elements LD4 may emit light with a luminance corresponding to a distributed current.

The driving current flowing to the fourth intermediate electrode CTE4 flows to the second electrode PE2 via the fifth light-emitting element LD5. Accordingly, in the fifth series stage SET5, the fifth light-emitting elements LD5 may emit light with a luminance corresponding to a distributed current.

In the above-described method, the driving current of the first sub-pixel SPXL1 may flow sequentially via the first light-emitting elements LD1 of the first series stage SET1, the second light-emitting elements LD2 of the second series stage SET2, the third light-emitting elements LD3 of the third series stage SET3, the fourth light-emitting elements LD4 of the fourth series stage SET4, and the fifth light-emitting elements LD5 of the fifth series stage SET5. Accordingly, the first sub-pixel SPXL1 may emit light with a luminance corresponding to a data signal supplied during each frame period.

In one or more embodiments, the electrode PE and the intermediate electrode CTE may be designed so that a width in the first direction DR1 is greater than a width in the second direction DR2. The electrode PE and the intermediate electrode CTE may be designed to have an area that may be sufficiently contact the first end EP1 or the second end EP2 of the corresponding light-emitting element LD even though a position is moved (or displaced) from a preset position in the first direction DR1 due to an overlay variation (or an overlay error) that may occur during a manufacturing process thereof. For example, each of the electrode PE and the intermediate electrode CTE may be designed to have the width of the first direction DR1 that is sufficiently greater (or wider) than a diameter D of each light-emitting element LD.

According to the above-described embodiments, as the first alignment electrode ALE1 and the second alignment electrode ALE2 extend in the first direction DR1 (or a horizontal direction) and are spaced apart from each other in the second direction DR2 (or a vertical direction), when the corresponding alignment signal is applied to each of the first alignment electrode ALE1 and the second alignment electrode ALE2, an electric field may be formed in the second direction DR2 between the first alignment electrode ALE1 and the second alignment electrode ALE2. By the electric field, each of the light-emitting elements LD may be aligned in the second direction DR2 so that, for example, the first end EP1 is adjacent to the second alignment electrode ALE2 and the second end EP2 is adjacent to the first alignment electrode ALE1.

After the light-emitting elements LD are aligned in the emission area EMA, the corresponding electrode PE and the corresponding intermediate electrode CTE may be formed on both ends EP1 and EP2 of each light-emitting element LD. In a process of forming the corresponding electrode PE and the corresponding intermediate electrode CTE, even though an overlay variation occurs in the first direction DR1 and the corresponding electrode PE and the corresponding intermediate electrode CTE are moved (or displaced) from a preset position with respect to the first direction DR1, as the corresponding electrode PE and the corresponding intermediate electrode CTE has the width of the first direction DR1 sufficiently greater (or larger) than the diameter D of each light-emitting element LD, a contact area with each light-emitting element LD may be secured. Accordingly, a non-contact defect between the corresponding electrode PE and each light-emitting element LD and a non-contact defect between the corresponding intermediate electrode CTE and each light-emitting element LD may be reduced or minimized, and thus light output efficiency of the first sub-pixel SPXL1 (or each pixel PXL) may be improved.

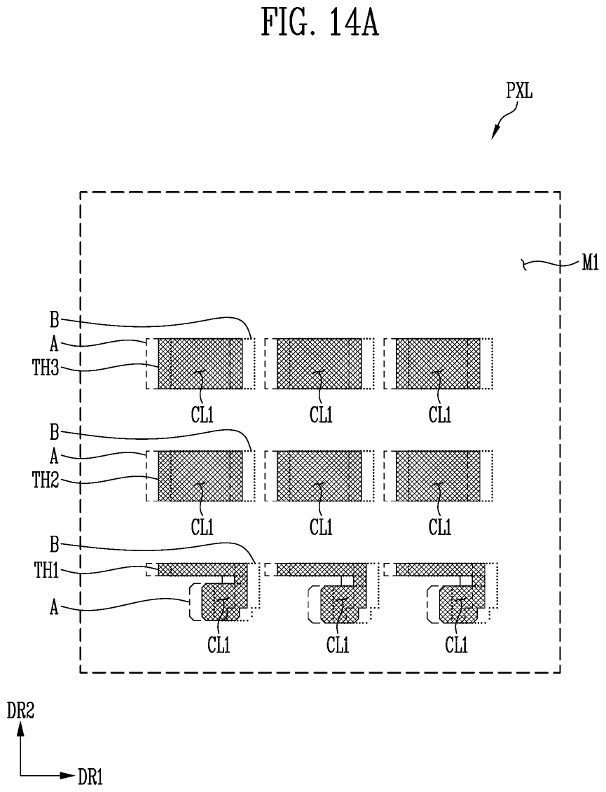

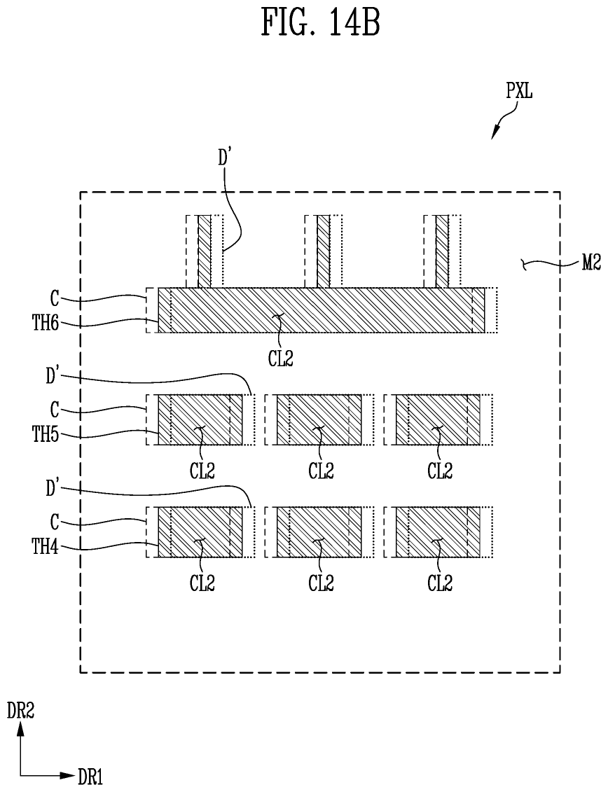

A case in which the electrode PE and the intermediate electrode CTE are displaced from the preset position with respect to the first direction DR1 during the process of forming the electrode PE and the intermediate electrode CTE is described with reference to FIGS. 14A and 14B.

Hereinafter, a stack structure of the first sub-pixel SPXL1 according to the above-described embodiments is mainly described with reference to FIGS. 10 to 13.

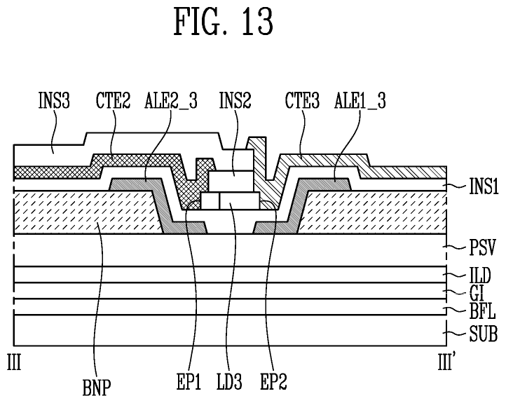

FIGS. 10 to 12 are schematic cross-sectional views taken along the line II˜II′ of FIG. 7, and FIG. 13 is a schematic cross-sectional view taken along the line III˜III′ of FIG. 7.

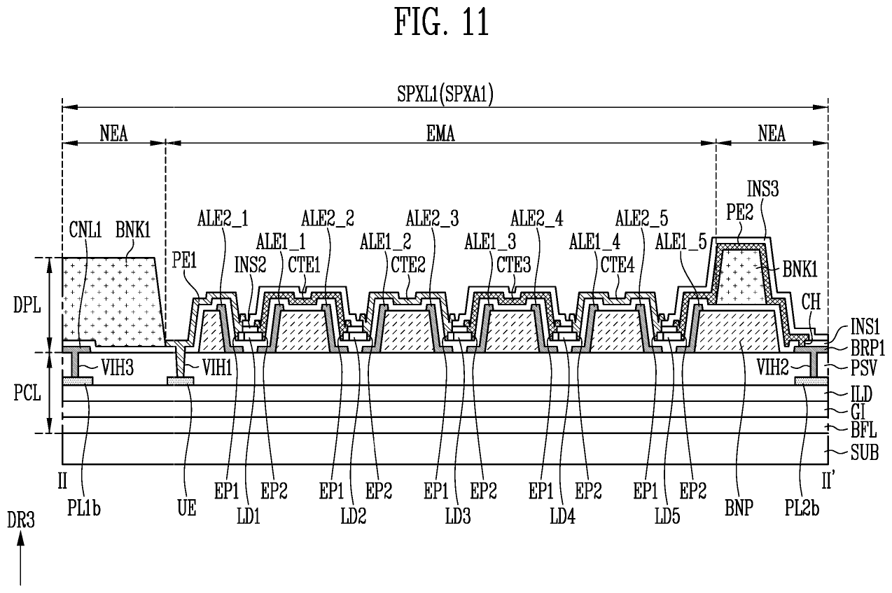

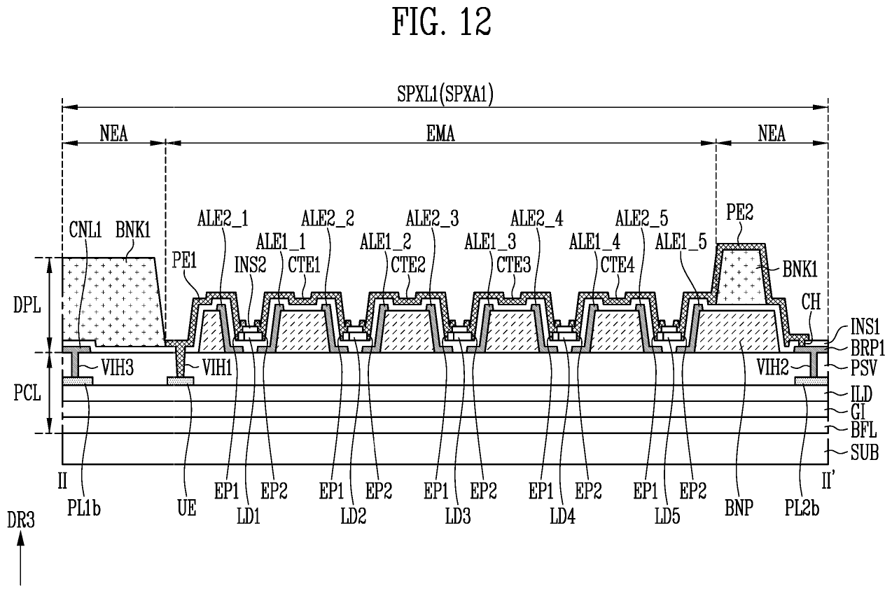

Embodiments of FIGS. 11 and 12 illustrate modified examples of the one or more other embodiments corresponding to FIG. 10 in relation to an operation of forming the first and second electrodes PE1 and PE2 and the first to fourth intermediate electrodes CTE1, CTE2, CTE3, and CTE4, and presence or absence of a third insulating layer INS3. For example, FIG. 11 discloses one or more embodiments in which the first electrode PE1, the second intermediate electrode CTE2, and the fourth intermediate electrode CTE4 are formed after the second electrode PE2, the first intermediate electrode CTE1, the third intermediate electrode CTE3, and the third insulating layer INS3 are formed, and FIG. 12 illustrates one or more embodiments in which the first and second electrodes PE1 and PE2 and the first to fourth intermediate electrodes CTE1, CTE2, CTE3, and CTE4 are formed by the same process.

In FIGS. 10 to 13, the first sub-pixel SPXL1 is simplified, such as showing each electrode as an electrode of a single layer and each insulating layer as only an insulating layer of a single layer, but the disclosure is not limited thereto.

Referring to FIGS. 10 to 13, a vertical direction on a cross-section is indicated as a third direction DR3.

Regarding the embodiments of FIGS. 10 to 13, a point different from the above-described embodiments is mainly described to avoid a repetitive description.

Referring to FIGS. 1 to 13, the first sub-pixel SPXL1 may include the substrate SUB, the pixel circuit layer PCL, and the display element layer DPL.

The pixel circuit layer PCL and the display element layer DPL may be located to overlap each other on one surface of the substrate SUB. For example, the first sub-pixel area SPXA1 of the substrate SUB may include the pixel circuit layer PCL located on one surface of the substrate SUB, and the display element layer DPL located on the pixel circuit layer PCL. The pixel circuit layer PCL may include the buffer layer BFL, the gate insulating layer GI, the interlayer insulating layer ILD, and the passivation layer PSV sequentially stacked on the substrate SUB. Because the pixel circuit layer PCL is the same as the pixel circuit layer PCL described with reference to FIGS. 5 and 6, a repeated detailed description thereof is omitted.

The display element layer DPL may include the first and second alignment electrodes ALE1 and ALE2, the light-emitting elements LD, the first and second electrodes PE1 and PE2, and the first to fourth intermediate electrodes CTE1, CTE2, CTE3, and CTE4.

The display element layer DPL may further include insulating patterns and/or insulating layers sequentially located on one surface of the pixel circuit layer PCL. For example, the display element layer DPL may further include a bank pattern BNP, a first insulating layer INS1, the first bank BNK1, a second insulating layer INS2, and the third insulating layer INS3.

The bank pattern BNP may be provided and/or formed on the pixel circuit layer PCL.

The bank pattern BNP, which also may be referred to as a support member or a wall pattern, may be provided and/or formed on the passivation layer PSV of the pixel circuit layer PCL. In one or more embodiments, the bank pattern BNP may be formed in a separation type pattern individually located under the first and second alignment electrodes ALE1 and ALE2 to overlap a portion of each of the first and second alignment electrodes ALE1 and ALE2. For example, the bank pattern BNP may be formed in a separation type pattern individually located under each of the (2-1)-th alignment electrode ALE2_1 and the (1-5)-th alignment electrode ALE1_5. In addition, the bank pattern BNP may be formed in a separation type pattern individually located under the (1-1)-th and (2-2)-th alignment electrodes ALE1_1 and ALE2_2, under the (1-2)-th and (2-3)-th alignment electrodes ALE1_2 and ALE2_3, under the (1-3)-th and (2-4)-th alignment electrodes ALE1_3 and ALE2_4, and under the (1-4)-th and (2-5)-th alignment electrodes ALE1_4 and ALE2_5.

According to one or more embodiments, the bank pattern BNP may have an opening or a recess corresponding to areas between the first and second alignment electrodes ALE1 and ALE2 in the emission area EMA, and may be formed in an integral pattern entirely connected in the display area DA.

The bank pattern BNP may protrude in the third direction DR3 on one surface of the pixel circuit layer PCL. Accordingly, one area of each of the first and second alignment electrodes ALE1 and ALE2 located on the bank pattern BNP may protrude in the third direction DR3 (or a thickness direction of the substrate SUB).

The bank pattern BNP may be an inorganic layer including an inorganic material or an organic layer including an organic material. According to one or more embodiments, the bank pattern BNP may include a single layer of organic layer and/or a single layer of inorganic layer, but is not limited thereto. According to one or more embodiments, the bank pattern BNP may be provided in a form of multiple layers in which at least one organic layer and at least one inorganic layer are stacked. However, a material of the bank pattern BNP is not limited to the above-described embodiments, and according to one or more embodiments, the bank pattern BNP may include a conductive material (or substance). A shape of the bank pattern BNP may be variously changed within a range capable of improving efficiency of the light emitted from the light-emitting element LD.

The bank pattern BNP may be utilized as a reflective member. For example, the bank pattern BNP may be utilized as a reflective member, which guides the light emitted from the light-emitting element LD in a desired direction, along with the first and second alignment electrodes ALE1 and ALE2 located thereon to improve light output efficiency of the first sub-pixel SPXL1.

The first and second alignment electrodes ALE1 and ALE2 may be provided and/or formed on the bank pattern BNP.

The first and second alignment electrodes ALE1 and ALE2 may be provided and/or formed on the pixel circuit layer PCL (or the passivation layer PSV) and the bank pattern BNP.

The first and second alignment electrodes ALE1 and ALE2 may be spaced apart from each other. The second alignment electrode ALE2 and the first alignment electrode ALE1 may be alternately arranged in an order of the (2-1)-th alignment electrode ALE2_1, the (1-1)-th alignment electrode ALE1_1, the (2-2)-th alignment electrode ALE2_2, the (1-2)-th alignment electrode ALE1_2, the (2-3)-th alignment electrode ALE2_3, the (1-3)-th alignment electrode ALE1_3, the (2-4)-th alignment electrode ALE2_4, the (1-4)-th alignment electrode ALE1_4, the (2-5)-th alignment electrode ALE2_5, and the (1-5)-th alignment electrode ALE1_5 along the second direction DR2. The first and second alignment electrodes ALE1 and ALE2 may be located on the same plane and may have the same thickness in the third direction DR3. The first and second alignment electrodes ALE1 and ALE2 may be concurrently/substantially simultaneously formed in the same process.

Each of the first and second alignment electrodes ALE1 and ALE2 may have a shape corresponding to a profile of the bank pattern BNP positioned thereunder.

The first and second alignment electrodes ALE1 and ALE2 may be formed of a material having a reflectance (e.g., predetermined reflectance) to allow the light emitted from the light-emitting element LD to proceed in the image display direction of the display device. For example, the first and second alignment electrodes ALE1 and ALE2 may be formed of a conductive material (or substance). The conductive material may include an opaque metal suitable for reflecting the light emitted from the light-emitting elements LD in the image display direction of the display device (or an upper direction of the display element layer DPL). The opaque metal may include, for example, a metal such as silver (Ag), magnesium (Mg), aluminum (Al), platinum (Pt), palladium (Pd), gold (Au), nickel (Ni), neodymium (Nd), iridium (Ir), chromium (Cr), titanium (Ti), and an alloy thereof. However, the material of the first and second alignment electrodes ALE1 and ALE2 is not limited to the above-described embodiments. According to one or more embodiments, the first and second alignment electrodes ALE1 and ALE2 may include a transparent conductive material (or substance). The transparent conductive material (or substance) may include a conductive oxide such as indium tin oxide (ITO), indium zinc oxide (IZO), zinc oxide (ZnOx), indium gallium zinc oxide (IGZO), and indium tin zinc oxide (ITZO), a conductive polymer such as poly(3,4-ethylenedioxythiophene) (PEDOT), and the like. When the first and second alignment electrodes ALE1 and ALE2 include a transparent conductive material (or substance), a separate conductive layer formed of an opaque metal for reflecting the light emitted from the light-emitting elements LD in the image display direction of the display device may be added. However, the material of the first and second alignment electrodes ALE1 and ALE2 is not limited to the above-described materials.

The first and second alignment electrodes ALE1 and ALE2 may be provided and/or formed as a single layer, but are not limited thereto. According to one or more embodiments, the first and second alignment electrodes ALE1 and ALE2 may be provided and/or formed as multiple layers in which at least two or more materials among metals, alloys, a conductive oxide, and conductive polymers are stacked. The first and second alignment electrodes ALE1 and ALE2 may be formed as multiple layers of two layers or more to reduce or minimize distortion due to signal delay when transmitting a signal to the both ends EP1 and EP2 of the light-emitting elements LD. For example, the first and second alignment electrodes ALE1 and ALE2 may be formed as multiple layers selectively further including at least one of at least one reflective electrode layer, at least one transparent electrode layer located on and/or under the reflective electrode layer, at least one conductive capping layer covering an upper portion of the reflective electrode layer and/or the transparent electrode layer.

When the first and second alignment electrodes ALE1 and ALE2 are formed of a conductive material having a reflectance, the light emitted from the both ends EP1 and EP2 of each of the light-emitting elements LD may further proceed in the image display direction of the display device. For example, when the first and second alignment electrodes ALE1 and ALE2 are located to face respective ends EP1 and EP2 of each of the light-emitting elements LD while having an inclined surface or a curved surface corresponding to the shape of the bank pattern BNP, the light emitted from the both ends EP1 and EP2 of each of the light-emitting elements LD may be reflected by the first and second alignment electrodes ALE1 and ALE2, and the light may further proceed in the image display direction of the display device. Accordingly, efficiency of the light emitted from the light-emitting elements LD may be improved.

In one or more embodiments, the (1-1)-th, (1-2)-th, (1-3)-th, (1-4)-th, and (1-5)-th alignment electrodes ALE1_1, ALE1_2, ALE1_3, ALE1_4, and ALE1_5 are formed integrally with the first connection line CNL1. The first connection line CNL1 may be electrically connected to the first horizontal power line PL1b positioned in the pixel circuit layer PCL through the third via hole VIH3. In the operation of aligning the light-emitting elements LD to the first sub-pixel area SPXA1 (or the emission area EMA), the first connection line CNL1 may receive a corresponding alignment signal from the first horizontal power line PL1b through the third via hole VIH3.

In one or more embodiments, the (2-1)-th, (2-2)-th, (2-3)-th, (2-4)-th, and (2-5)-th alignment electrodes ALE2_1, ALE2_2, ALE2_3, ALE2_4, and ALE2_5 are formed integrally with the second connection line CNL2. The second connection line CNL2 may be electrically connected to the second horizontal power line PL2b positioned in the pixel circuit layer PCL through the corresponding second via hole VIH2. In the operation of aligning the light-emitting elements LD to the first sub-pixel area SPXA1 (or the emission area EMA), the second connection line CNL2 may receive a corresponding alignment signal from the second horizontal power line PL2b through the second via hole VIH2 positioned in the third sub-pixel area SPXA3 of the third sub-pixel SPXL3.

In one or more embodiments, the first bridge pattern BRP1 spaced apart from the first and second alignment electrodes ALE1 and ALE2 may be located in the first sub-pixel area SPXA1. The first bridge pattern BRP1 may be formed in the same process, and may include the same material as the first and second alignment electrodes ALE1 and ALE2.

The first bridge pattern BRP1 may be electrically connected to the second horizontal power line PL2b through the second via hole VIH2 passing through the passivation layer PSV. In addition, the first bridge pattern BRP1 may be electrically connected to the second electrode PE2 through the contact hole CH passing through the first insulating layer INS1. In one or more embodiments, the first bridge pattern BRP1 may be a medium that electrically connects the second horizontal power line PL2b positioned in the pixel circuit layer PCL and the second electrode PE2. According to one or more embodiments, when the first bridge pattern BRP1 is omitted, the second horizontal power line PL2b and the second electrode PE2 may directly contact each other through the second via hole VIH2 to thereby be electrically connected.

The second bridge pattern BRP2 may be located in the second sub-pixel area SPXA2 of the second sub-pixel SPXL2 to be spaced apart from the first bridge pattern BRP1, and the third bridge pattern BRP3 may be located in the sub-pixel area SPXA3 of the third sub-pixel SPXL3. The third bridge pattern BRP3 may be formed integrally with the second connection line CNL2.

The first insulating layer INS1 may be located on the first and second alignment electrodes ALE1 and ALE2, the first to third bridge patterns BRP1 to BRP3, and the first and second connection lines CNL1 and CNL2.

The first insulating layer INS1 may be entirely provided and/or formed on the first and second alignment electrodes ALE1 and ALE2, the first to third bridge patterns BRP1 to BRP3, the first and second connection lines CNL1 and CNL2, and the bank pattern BNP. The first insulating layer INS1 may be partially opened in (e.g., at respective portions of) the emission area EMA and the non-emission area NEA to expose configurations positioned thereunder. For example, the first insulating layer INS1 may be partially opened to include/define a first via hole VIH1 corresponding to the first via hole VIH1 of the passivation layer PSV in the emission area EMA and a contact hole CH exposing one area of the first bridge pattern BRP1 in the non-emission area NEA.

The first insulating layer INS1 may be formed of an inorganic insulating layer formed of an inorganic material. For example, the first insulating layer INS1 may include at least one of silicon nitride (SiNₓ), silicon oxide (SiOₓ), silicon oxynitride (SiOₓN_{y}), and a metal oxide such as aluminum oxide (AlOₓ).

According to one or more embodiments, the first insulating layer INS1 may be provided as a single layer or multiple layers. When the first insulating layer INS1 is provided as the multiple layers, the first insulating layer INS1 may be provided as a distributed Bragg reflector structure in which a first layer and a second layer having different refractive indices formed of an inorganic layer are alternately stacked.

The first bank BNK1 may be located on the insulating layer INS1. The first bank BNK1 may be provided and/or formed on the first insulating layer INS1 in the non-emission area NEA. The first bank BNK1 may surround the emission area EMA of the first sub-pixel SPXL1, and may be formed between adjacent sub-pixels to configure a pixel defining layer that partitions the emission area EMA of each of the sub-pixels. In an operation of supplying (or inputting) the light-emitting elements LD to the emission area EMA of the first sub-pixel SPXL1, the first bank BNK1 may configure a dam structure that reduces or prevents the likelihood of a solution (or an ink), in which the light-emitting elements LD are mixed, from flowing to the emission area EMA (e.g., the emission area EMA of the second sub-pixel SPXL2 and/or the emission area EMA of the third sub-pixel SPXL3) of an adjacent sub-pixel or controls an appropriate amount of solution to be supplied to each emission area EMA.

The first bank BNK1 may be configured to include at least one light blocking material and/or reflective material (or a scattering material) to reduce or prevent a light leakage defect in which light (or rays) leaks between adjacent sub-pixels. According to one or more embodiments, the first bank BNK1 may include a transparent material (or substance). The transparent material may include, for example, polyamides resin, polyimides resin, and the like, but is not limited thereto. According to one or more other embodiments, a reflective material layer may be separately provided and/or formed on the first bank BNK1 to further improve efficiency of light emitted from each sub-pixel.

The light-emitting elements LD may be supplied to the emission area EMA of the first sub-pixel SPXL1 surrounded by (or defined) by the first bank BNK1. For example, the light-emitting elements LD may be supplied (or input) to the emission area EMA through an inkjet printing method or the like, and each of the light-emitting elements LD may be aligned on a surface of the first insulating layer INS1 of an area between the first alignment electrode ALE1 and the second alignment electrode ALE2 by a vertical electric field formed by a signal (e.g., predetermined signal, or an alignment signal) applied to each of the first connection line CNL1 (or the first alignment electrode ALE1) and the second connection line CNL2 (or the second alignment electrode ALE2). For example, the light-emitting elements LD supplied to the emission area EMA may be arranged so that the first ends EP1 face the second alignment electrode ALE2 and the second ends EP2 face the first alignment electrode ALE1.

The light-emitting elements LD may include the first light-emitting element LD1, the second light-emitting element LD2, the third light-emitting element LD3, the fourth light-emitting element LD4, and the fifth light-emitting element LD5.

The second insulating layer INS2 (or insulating pattern) may be located on each of the first, second, third, fourth, and fifth light-emitting elements LD1, LD2, LD3, LD4, and LD5. The second insulating layer INS2 may be positioned on the first, second, third, fourth, and fifth light-emitting elements LD1, LD2, LD3, LD4, and LD5, and may partially cover an outer circumferential surface (or surface) of each of the first, second, third, fourth, and fifth light-emitting elements LD1, LD2, LD3, LD4, and LD5 to expose the first end EP1 and the second end EP2 of each of the first, second, third, fourth, and fifth light-emitting elements LD1, LD2, LD3, LD4, and LD5 to the outside.

The second insulating layer INS2 may include an inorganic insulating layer including an inorganic material or an organic insulating layer. For example, the second insulating layer INS2 may include an inorganic insulating layer suitable for protecting the active layer 12 of each of the first, second, third, fourth, and fifth light-emitting elements LD1, LD2, LD3, LD4, and LD5 from external oxygen, moisture, and the like. However, the disclosure is not limited thereto, and the second insulating layer INS2 may be configured of an organic insulating layer including an organic material according to a design condition of the display device to which the first, second, third, fourth, and fifth light-emitting elements LD1, LD2, LD3, LD4, and LD5 are applied. The second insulating layer INS2 may be configured as a single layer or multiple layers.

When a gap (or a space) exists between the first insulating layer INS1 and the light-emitting elements LD before formation of the second insulating layer INS2, the gap may be filled with the second insulating layer INS2 in a process of forming the second insulating layer INS2. In this case, the second insulating layer INS2 may be configured of an organic insulating layer advantageous for filling the gap between the first insulating layer INS1 and the light-emitting elements LD, but is not limited thereto.

The likelihood of the first, second, third, fourth, and fifth light-emitting elements LD1, LD2, LD3, LD4, and LD5 being separated from an aligned position may be reduced or prevented by forming the second insulating layer INS2 on the first, second, third, fourth, and fifth light-emitting elements LD1, LD2, LD3, LD4, and LD5 of which the alignment in the first emission area EMA1 is completed.

Different electrodes among the first electrode PE1 (or the first pixel electrode), the second electrode PE2 (or the second pixel electrode), and the intermediate electrode CTE may be respectively formed on respective ends of the first, second, third, fourth, and fifth light-emitting elements LD1, LD2, LD3, LD4, and LD5 that are not covered by the second insulating layer INS2, for example, the first and second ends EP1 and EP2. For example, the first electrode PE1 may be formed on the first end EP1 of the first light-emitting element LD1, the first intermediate electrode CTE1 may be formed on the second end EP2 of the first light-emitting element LD1 and on the first end EP1 of the second light-emitting element LD2, the second intermediate electrode CTE2 may be formed on the second end EP2 of the second light-emitting element LD2 and on the first end EP1 of the third light-emitting element LD3, the third intermediate electrode CTE3 may be formed on the second end EP2 of the third light-emitting element LD3 and on the first end EP1 of the fourth light-emitting element LD4, the fourth intermediate electrode CTE4 may be formed on the second end EP2 of the fourth light-emitting element LD4 and on the first end EP1 of the fifth light-emitting element LD5, and the second electrode PE2 may be formed on the second end EP2 of the fifth light-emitting element LD5.

The first electrode PE1 may be located on the (2-1)-th alignment electrode ALE2_1 to overlap the (2-1)-th alignment electrode ALE2_1, and the second electrode PE2 may be located on the (1-5)-th alignment electrode ALE1_5 to overlap the (1-5)-th alignment electrodes ALE1_5.

In one or more embodiments, the first electrode PE1 may be electrically connected to the second storage electrode UE (or the upper electrode) of the first pixel circuit PXC1 through the first via hole VIH1 passing through the first insulating layer INS1 and the passivation layer PSV in the emission area EMA. The second electrode PE2 may be electrically connected to the second horizontal power line PL2b connected to the second horizontal power line PL2b connected to the first pixel circuit PXC1 through the contact hole CH passing through the first insulating layer INS1, and the second via hole VIH2 passing through the first bridge pattern BRP1 and the passivation layer PSV.

The first intermediate electrode CTE1 may be located on each of the (1-1)-th alignment electrode ALE1_1 and the (2-2)-th alignment electrode ALE2_2 to overlap each of the (1-1)-th alignment electrode ALE1_1 and the (2-2)-th alignment electrode ALE2_2. The second intermediate electrode CTE2 may be located on each of the (1-2)-th alignment electrode ALE1_2 and the (2-3)-th alignment electrode ALE2_3 to overlap each of the (1-2)-th alignment electrode ALE1_2 and the (2-3)-th alignment electrode ALE2_3. The third intermediate electrode CTE3 may be located on each of the (1-3)-th alignment electrode ALE1_3 and the (2-4)-th alignment electrode ALE2_4 to overlap each of the (1-3)-th alignment electrode ALE1_3 and the (2-4)-th alignment electrode ALE2_4. The fourth intermediate electrode CTE4 may be located on each of the (1-4)-th alignment electrode ALE1_4 and the (2-5)-th alignment electrode ALE2_5 to overlap each of the (1-4)-th alignment electrode ALE1_4 and the (2-5)-th alignment electrode ALE2_5.

In one or more embodiments, the first electrode PE1, the first intermediate electrode CTE1, the second intermediate electrode CTE2, the third intermediate electrode CTE3, the fourth intermediate electrode CTE4, and the second electrode PE2 may be formed in the same layer or different layers. For example, a mutual position and/or a formation order of the first electrode PE1, the first intermediate electrode CTE1, the second intermediate electrode CTE2, the third intermediate electrode CTE3, the fourth intermediate electrode CTE4, and the second electrode PE2 may be variously changed according to one or more embodiments.

In the one or more other embodiments corresponding to FIG. 10, the first electrode PE1, the second intermediate electrode CTE2, and the fourth intermediate electrode CTE4 may be formed first on the second insulating layer INS2. The first electrode PE1 may directly contact the first end EP1 of the first light-emitting element LD1. The second intermediate electrode CTE2 may direct contact the second end EP2 of the second light-emitting element LD2 and the first end EP1 of the third light-emitting element LD3 to be connected between the second light-emitting element LD2 and the third light-emitting element LD3. The fourth intermediate electrode CTE4 may directly contact the second end EP2 of the fourth light-emitting element LD4 and the first end EP1 of the fifth light-emitting element LD5 to be connected between the fourth light-emitting element LD4 and the fifth light-emitting element LD5. Thereafter, the third insulating layer INS3 may be formed in the emission area EMA to cover the first electrode PE1, the second intermediate electrode CTE2, and the fourth intermediate electrode CTE4. The first electrode PE1, the second intermediate electrode CTE2, and the fourth intermediate electrode CTE4 may be concurrently/substantially simultaneously or successively formed.

The third insulating layer INS3 may be positioned on the first electrode PE1, the second intermediate electrode CTE2, and the fourth intermediate electrode CTE4 to cover the first electrode PE1, the second intermediate electrode CTE2, and the fourth intermediate electrode CTE4 (or reduce or prevent the likelihood of the first electrode PE1, the second intermediate electrode CTE2, and the fourth intermediate electrode CTE4 being exposed to the outside), thereby reducing or preventing corrosion or the like of the first electrode PE1, the second intermediate electrode CTE2, and the fourth intermediate electrode CTE4.

The third insulating layer INS3 may include an inorganic insulating layer formed of an inorganic material or an organic insulating layer formed of an organic material. For example, the third insulating layer INS3 may include at least one of silicon nitride (SiNₓ), silicon oxide (SiOₓ), silicon oxynitride (SiOₓN_{y}), and a metal oxide such as aluminum oxide (AlOₓ), but is not limited thereto. In addition, the third insulating layer INS3 may be formed as a single layer or multiple layers.

The first intermediate electrode CTE1, the third intermediate electrode CTE3, and the second electrode PE2 may be formed on the third insulating layer INS3. The second electrode PE2 may directly contact the second end EP2 of the fifth light-emitting element LD5. The first intermediate electrode CTE1 may directly contact the second end EP2 of the first light-emitting element LD1 and the first end EP1 of the second light-emitting element LD2 to be connected between the first light-emitting element LD1 and the second light-emitting element LD2. The third intermediate electrode CTE3 may direct contact the second end EP2 of the third light-emitting element LD3 and the first end EP1 of the fourth light-emitting element LD1 to be connected between the third light-emitting element LD3 and the fourth light-emitting element LD4. The first intermediate electrode CTE1, the third intermediate electrode CTE3, and the second electrode PE2 may be concurrently/substantially simultaneously or successively formed.

In the one or more other embodiments corresponding to FIG. 11, the first intermediate electrode CTE1, the third intermediate electrode CTE3, and the second electrode PE2 may be formed first on the second insulating layer INS2. The first intermediate electrode CTE1, the third intermediate electrode CTE3, and the second electrode PE2 may be concurrently/substantially simultaneously or successively formed. Thereafter, the third insulating layer INS3 may be formed to cover the first intermediate electrode CTE1, the third intermediate electrode CTE3, and the second electrode PE2. Also, the first electrode PE1, the second intermediate electrode CTE2, and the fourth intermediate electrode CTE4 may be formed in the emission area EMA in which the third insulating layer INS3 is formed.

As in the embodiments of FIGS. 10 and 11, when electrodes located on the first end EP1 and the second end EP2 of each light-emitting element LD are located in different layers, the electrodes may be electrically separated stably, and thus the likelihood of a short defect between the electrodes may be reduced or prevented.

In the one or more other embodiments corresponding to FIG. 12, the first electrode PE1, the first intermediate electrode CTE1, the second intermediate electrode CTE2, the third intermediate electrode CTE3, the fourth intermediate electrode CTE4, and the second electrode PE2 may be located in the same layer of the display element layer DPL, and may be concurrently/substantially simultaneously or sequentially formed. In this case, the third insulating layer INS3 may be omitted. In the one or more other embodiments corresponding to FIG. 12, when electrodes located on the first end EP1 and the second end EP2 of each light-emitting element LD are located in the same layer and concurrently/substantially simultaneously formed, a manufacturing process of the first sub-pixel SPXL1 may be simplified and process efficiency may be improved. In this case, the third insulating layer INS3 may be omitted.

The first electrode PE1, the first intermediate electrode CTE1, the second intermediate electrode CTE2, the third intermediate electrode CTE3, the fourth intermediate electrode CTE4, and the second electrode PE2 may be formed of various transparent conductive materials to allow the light emitted from each of the light-emitting elements LD to proceed in the image display direction (e.g., the third direction DR3) of the display device without loss. For example, the first electrode PE1, the first intermediate electrode CTE1, the second intermediate electrode CTE2, the third intermediate electrode CTE3, the fourth intermediate electrode CTE4, and the second electrode PE2 may include at least one of various transparent conductive materials (or substances) including indium tin oxide (ITO), indium zinc oxide (IZO), zinc oxide (ZnOₓ), indium gallium zinc oxide (IGZO), indium tin zinc oxide (ITZO), and the like, and may be configured to be substantially transparent or translucent to satisfy a light transmittance (e.g., predetermined light transmittance, or transmission). However, the material of the first electrode PE1, the first intermediate electrode CTE1, the second intermediate electrode CTE2, the third intermediate electrode CTE3, the fourth intermediate electrode CTE4, and the second electrode PE2 is not limited to the above-described embodiments. According to one or more embodiments, the first electrode PE1, the first intermediate electrode CTE1, the second intermediate electrode CTE2, the third intermediate electrode CTE3, the fourth intermediate electrode CTE4, and the second electrode PE2 may be formed of various opaque conductive materials (or substances). The first electrode PE1, the first intermediate electrode CTE1, the second intermediate electrode CTE2, the third intermediate electrode CTE3, the fourth intermediate electrode CTE4, and the second electrode PE2 may be formed as a single layer or multiple layers.

According to one or more embodiments, at least one overcoat layer (e.g., a layer for planarizing an upper surface of the display element layer DPL) may be further located on the first electrode PE1, the first intermediate electrode CTE1, the second intermediate electrode CTE2, the third intermediate electrode CTE3, the fourth intermediate electrode CTE4, and the second electrode PE2.

According to one or more other embodiments, an optical layer may be selectively located on the display element layer DPL of the first sub-pixel SPXL1. For example, the optical layer may further include a color conversion layer including color conversion particles that convert the light emitted from the light-emitting elements LD into light of a corresponding color.

FIG. 14A is a plan view schematically illustrating a first mask M1 forming a first electrode, a second intermediate electrode, and a fourth intermediate electrode in a pixel PXL according to one or more embodiments.

Referring to FIGS. 7, 10, and 14A, the first mask M1 according to one or more embodiments may include/define first, second, and third through holes TH1, TH2, and TH3. The first mask M1 may be a mask used to form the first electrode PE1, the second intermediate electrode CTE2, and the fourth intermediate electrode CTE4. For example, the first mask M1 may be a fine metal mask (FMM). The first mask M1 may be manufactured by forming a through hole (or a hole) in a metal plate and then stretching the metal plate.

The first, second, and third through holes TH1, TH2, and TH3 may be spaced apart from each other. The first through hole TH1 may indicate a formation position of the first electrode PE1 of each of the first, second, and third sub-pixels SPXL1, SPXL2, and SPXL3, and a size of the first though hole TH1 may be identical to or similar to that of the first electrode PE1. The second through hole TH2 may indicate a formation position of the second intermediate electrode CTE2 of each of the first, second, and third sub-pixels SPXL1, SPXL2 and SPX3, and a size of the second through hole TH2 may be identical to or similar to that of the second intermediate electrode CTE2. The third through hole TH3 may indicate a formation position of the fourth intermediate electrode CTE4 of each of the first, second, and third sub-pixels SPXL1, SPXL2, and SPXL3, and a size of the third through hole TH3 may be identical to or similar to that of the fourth intermediate electrode CTE4. Each of the first, second, and third through holes TH1, TH2, and TH3 may expose one area of the first conductive layer CL1, which is a base conductive material of the first electrode PE1, the second intermediate electrode CTE2, and the fourth intermediate electrode CTE4 of each of the first, second, and third sub-pixels SPXL1, SPXL2, and SPXL3.

After the light-emitting elements LD are aligned in the emission area EMA of each of the first, second, and third sub-pixels SPXL1, SPXL2, and SPXL3, the first conductive layer CL1 may be entirely coated on the pixel area (refer to the pixel area PXA of FIG. 3) of each pixel PXL. Subsequently, after forming a photoresist on the first conductive layer CL1, a photolithography process using the first mask M1 is performed. An exposure machine used in an exposure process of the photolithography process scans the pixel PXL in a direction parallel to the second direction DR2. At this time, due to a characteristic of the exposure machine, an overlay variation (or an overlay error) of the first conductive layer CL1 may occur in the first direction DR1, which is a direction perpendicular to a scan direction (e.g., the second direction DR2) of the exposure machine. For example, the first electrode PE1 may not be formed at a preset position (or a position corresponding to the first through hole TH1 of the first mask M1), and may be formed at a first point A or a second point B, which is moved from the preset position with respect to the first direction DR1. In addition, the second intermediate electrode CTE2 may not be formed at a preset position (or a position corresponding to the second through hole TH2 of the first mask M1), and may be formed at a first point A or a second point B, which is moved from the preset position with respect to the first direction DR1. Similarly, the fourth intermediate electrode CTE4 may not be formed at a preset position (or a position corresponding to the third through hole TH3 of the first mask M1), and may be formed at a first point A or a second point B, which is moved from the preset position with respect to the first direction DR1.

As described above, even though each of the first electrode PE1, the second intermediate electrode CTE2, and the fourth intermediate electrode CTE4 is formed at a point moved from the preset position with respect to the first direction DR1, each of the first electrode PE1, the second intermediate electrode CTE2, and the fourth intermediate electrode CTE4 may sufficiently contact one end of a corresponding light-emitting element LD aligned in the second direction DR2, thereby reducing or preventing the likelihood of a defect of non-contact with the corresponding light-emitting element LD.

For example, even though the first electrode PE1 is formed at any point moved from the preset position with respect to the first direction DR1, as a width of the first electrode PE1 of the first direction DR1 is designed to be relatively greater than a diameter of the first light-emitting element LD1, a contact area between the first electrode PE1 and the first end EP1 of the first light-emitting element LD1 may be further secured. Accordingly, the first electrode PE1 in which an overlay variation occurs may sufficiently contact the first end EP1 of the first light-emitting element LD1.

In addition, even though the second intermediate electrode CTE2 is formed at any point moved from the preset position with respect to the first direction DR1, as a width of the second intermediate electrode CTE2 of the first direction DR1 is designed to be relatively greater than a diameter of each of the second and third light-emitting elements LD2 and LD3, a contact area between the second intermediate electrode CTE2 and the second end EP2 of the second light-emitting element LD2 and a contact area between the second intermediate electrode CTE2 and the first end EP1 of the third light-emitting element LD3 may be further secured. Accordingly, the second intermediate electrode CTE2 in which an overlay variation occurs may sufficiently contact the second end EP2 of the second light-emitting element LD2 and the first end EP1 of the third light-emitting element LD3.

Similarly, even though the fourth intermediate electrode CTE4 is formed at any point moved from the preset position with respect to the first direction DR1, as a width of the fourth intermediate electrode CTE4 of the first direction DR1 is designed to be relatively greater than a diameter of each of the fourth and fifth light-emitting elements LD4 and LD5, a contact area between the fourth intermediate electrode CTE4 and the second end EP2 of the fourth light-emitting element LD4 and a contact area between the fourth intermediate electrode CTE4 and the first end EP1 of the fifth light-emitting element LD5 may be further secured. Accordingly, the fourth intermediate electrode CTE4 in which an overlay variation occurs may sufficiently contact the second end EP2 of the fourth light-emitting element LD4 and the first end EP1 of the fifth light-emitting element LD5.

According to the above-described embodiments, even though the first electrode PE1, the second intermediate electrode CTE2, and the fourth intermediate electrode CTE4 are formed at any point moved from the preset position with respect to the first direction DR1, as the first electrode PE1, the second intermediate electrode CTE2, and the fourth intermediate electrode CTE4 have the width of the first direction DR1 relatively greater than the diameter of the corresponding light-emitting element LD, a contact defect between each of the first electrode PE1, the second intermediate electrode CTE2, and the fourth intermediate electrode CTE4 and the corresponding light-emitting element LD may be reduced or minimized.

FIG. 14B is a plan view schematically illustrating a second mask M2 forming a first intermediate electrode, a third intermediate electrode, and a second electrode in a pixel PXL according to one or more embodiments.

Referring to FIGS. 7, 10, and 14B, the second mask M2 according to one or more embodiments may include fourth, fifth, and sixth through holes TH4, TH5, and TH6. The second mask M2 may be a mask used to form the first intermediate electrode CTE1, the third intermediate electrode CTE3, and the second electrode PE2. For example, the second mask M2 may be a fine metal mask (FMM). The second mask M2 may be manufactured by forming a through hole (or a hole) in a metal plate and then stretching the metal plate.

The fourth, fifth, and sixth through holes TH4, TH5, and TH6 may be spaced apart from each other. The fourth through hole TH4 may indicate a formation position of the first intermediate electrode CTE1 of each of the first, second, and third sub-pixels SPXL1, SPXL2, and SPXL3, and a size of the fourth through hole TH4 may be identical to or similar to that of the first intermediate electrode CTE1. The fifth through hole TH5 may indicate a formation position of the third intermediate electrode CTE3 of each of the first, second, and third sub-pixels SPXL1, SPXL2, and SPXL3, and a size of the fifth through hole TH5 may be identical to or similar to that of the third intermediate electrode CTE3. The sixth through hole TH6 may indicate a formation position of the second electrode PE2 of each of the first, second, and third sub-pixels SPXL1, SPXL2, and SPXL3, and a size of the sixth through hole TH6 may be identical to or similar to that of the second electrode PE2. Each of the fourth, fifth, and sixth through holes TH4, TH5, and TH6 may expose one area of the second conductive layer CL2, which is a base conductive material of the first intermediate electrode CTE1, the third intermediate electrode CTE3, and the second electrode PE2 of each of the first, second, and third sub-pixels SPXL1, SPXL2, and SPXL3.

After the first electrode PE1, the second intermediate electrode CTE2, and the fourth intermediate electrode CTE4 are formed in the emission area EMA of each of the first, second, and third sub-pixels SPXL1, SPXL2, and SPXL3, the second conductive layer CL2 may be entirely coated on the pixel area (refer to the pixel area PXA of FIG. 3) of each pixel PXL. Subsequently, after a photoresist is formed on the second conductive layer CL2, a photolithography process using the second mask M2 is performed. An exposure machine used in an exposure process of the photolithography process scans the pixel PXL in a direction parallel to the second direction DR2. At this time, due to a characteristic of the exposure machine, an overlay variation (or an overlay error) of the second conductive layer CL2 may occur in the first direction DR1, which is a direction perpendicular to a scan direction (e.g., the second direction DR2) of the exposure machine. For example, the first intermediate electrode CTE1 may not be formed at a preset position (or a position corresponding to the fourth through hole TH4 of the second mask M2), and may be formed at a third point C or a fourth point D′ moved from the preset position with respect to the first direction DR1. In addition, the third intermediate electrode CTE3 may not be formed at a preset position (or a position corresponding to the fifth through hole TH5 of the second mask M2), and may be formed at a third point C or a fourth point D′ moved from the preset position with respect to the first direction DR1. Similarly, the second electrode PE2 may not be formed at a preset position (or a position corresponding to the sixth through hole TH6 of the second mask M2), and may be formed at a third point C or a fourth point D′ moved from the preset position with respect to the first direction DR1.

As described above, even though each of the first intermediate electrode CTE1, the third intermediate electrode CTE3, and the second electrode PE2 is formed at a point moved from the preset position with respect to the first direction DR1, each of the first intermediate electrode CTE1, the third intermediate electrode CTE3, and the second electrode PE2 may sufficiently contact another end of a corresponding light-emitting element LD aligned in the second direction DR2, thereby reducing or preventing the likelihood of a defect of non-contact with the corresponding light-emitting element LD.

For example, even though the first intermediate electrode CTE1 is formed at any point moved from the preset position with respect to the first direction DR1, as a width of the first intermediate electrode CTE1 of the first direction DR1 is designed to be relatively greater than a diameter of each of the first and second light-emitting elements LD1 and LD2, a contact area between the first intermediate electrode CTE1 and the second end EP2 of the first light-emitting element LD1 and a contact area between the first intermediate electrode CTE1 and the first end EP1 of the second light-emitting element LD2 may be further secured. Accordingly, the first intermediate electrode CTE1 in which the overlay variation occurs may sufficiently contact the second end EP2 of the first light-emitting element LD1 and the first end EP1 of the second light-emitting element LD2.

In addition, even though the third intermediate electrode CTE3 is formed at any point moved from the preset position with respect to the first direction DR1, as a width of the third intermediate electrode CTE3 of the first direction DR1 is designed to be relatively greater than a diameter each of the third and fourth light-emitting elements LD3 and LD4, a contact area between the third intermediate electrode CTE3 and the second end EP2 of the third light-emitting element LD3 and a contact area between the intermediate electrode CTE3 and the first end EP1 of the fourth light-emitting element LD4 may be further secured. Accordingly, the third intermediate electrode CTE3 in which the overlay variation occurs may sufficiently contact the second end EP2 of the third light-emitting element LD3 and the first end EP1 of the fourth light-emitting element LD4.

Similarly, even though the second electrode PE2 is formed at any point moved from the preset position with respect to the first direction DR1, as a width of the second electrode PE2 of the first direction DR1 is designed to be relatively greater than a diameter of the fifth light-emitting element LD5, a contact area between the second electrode PE2 and the second end EP2 of the fifth light-emitting element LD5 may be further secured. Accordingly, the second electrode PE2 in which the overlay variation occurs may sufficiently contact the second end EP2 of the fifth light-emitting element LD5.

According to the above-described embodiments, even though the first intermediate electrode CTE1, the third intermediate electrode CTE3, and the second electrode PE2 are formed at any point moved from the preset position with respect to the first direction DR1, as the first intermediate electrode CTE1, the third intermediate electrode CTE3, and the second electrode PE2 have the width relatively greater than the diameter of the corresponding light-emitting element LD, a contact defect between each of the first intermediate electrode CTE1, the third intermediate electrode CTE3, and the second electrode PE2 and the corresponding light-emitting element LD may be reduced or minimized.

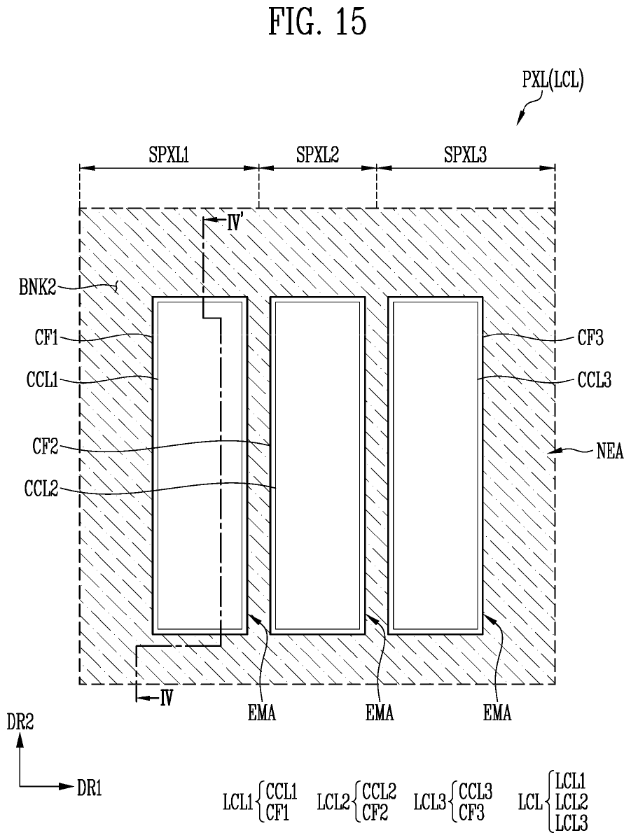

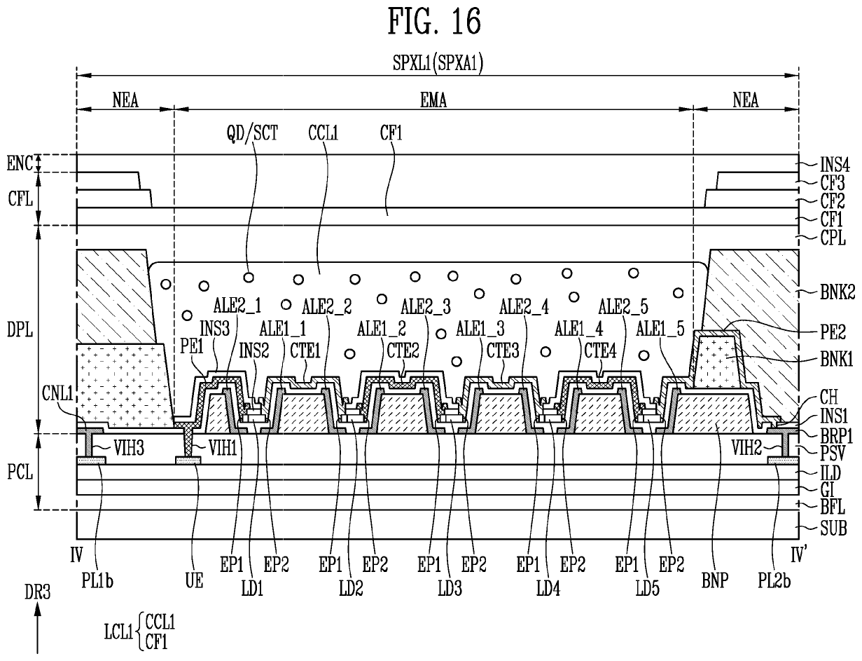

FIG. 15 is a plan view schematically illustrating a pixel area including an optical layer LCL of the pixel PXL shown in FIG. 3, and FIGS. 16 to 18 are schematic cross-sectional views taken along the line IV˜IV′ of FIG. 15.

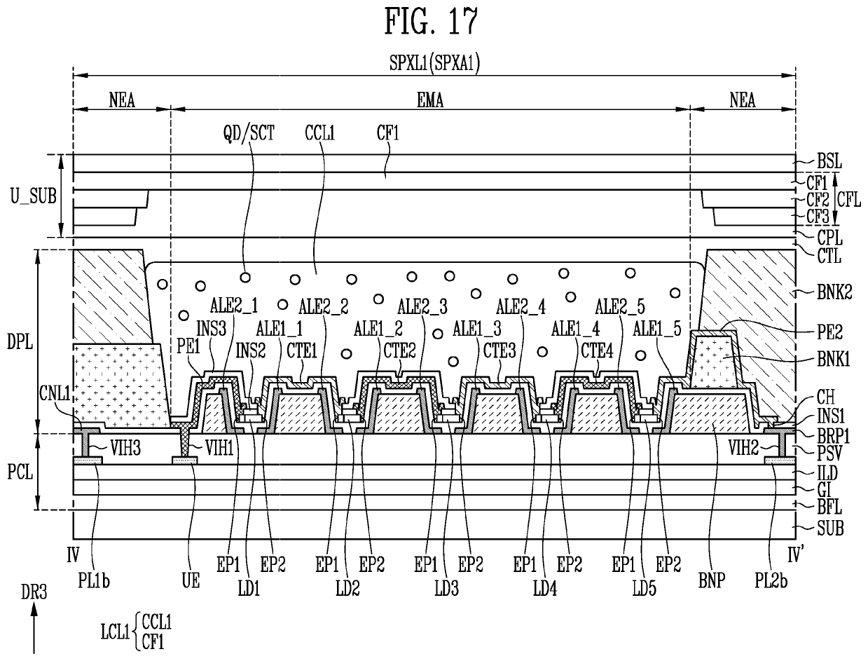

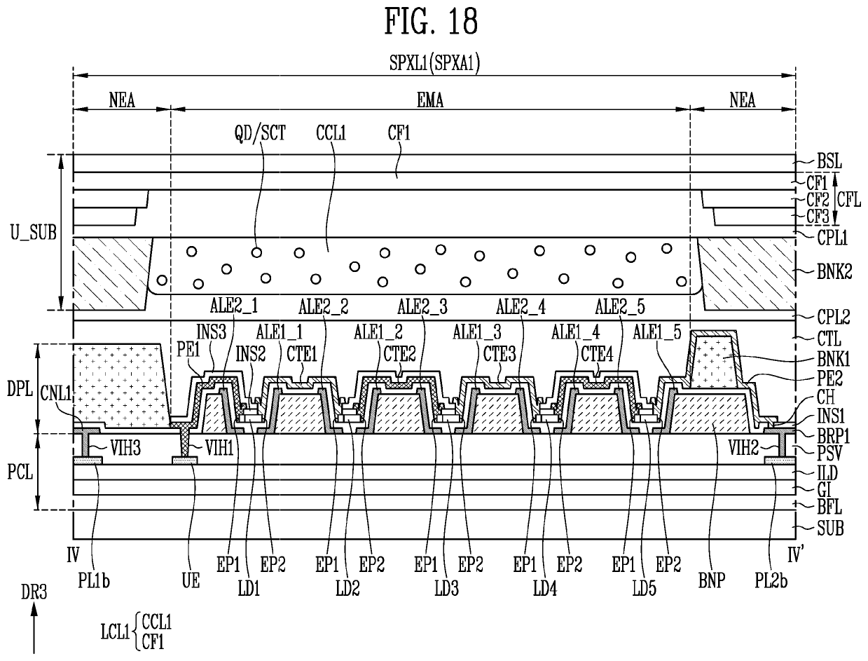

FIGS. 16 to 18 illustrate different modified examples in relation to a position of a first color conversion layer CCL1. For example, FIG. 16 discloses one or more embodiments in which the first color conversion layer CCL1 and a first color filter CF1 are positioned on the first and second electrodes PE1 and PE2 through a successive process, FIG. 17 discloses one or more embodiments in which an upper substrate U_SUB including the first color filter CF1 on the display element layer DPL including the first color conversion layer CCL1 is positioned on the display element layer DPL through an adhesion process using the intermediate layer CTL, and FIG. 18 discloses one or more embodiments in which an upper substrate U_SUB including the first color conversion layer CCL1 and the first color filter CF1 is positioned on the display element layer DPL through an adhesion process using the intermediate layer CTL.

Regarding the embodiments of FIGS. 15 to 18, a point different from the above-described embodiments is mainly described to avoid a repetitive description.

Referring to FIGS. 1 to 18, the optical layer LCL of the pixel PXL may include a first optical layer LCL1 positioned in the emission area EMA of the first sub-pixel SPXL1, a second optical layer LCL2 positioned in the emission area EMA of the second sub-pixel SPXL2, and a third optical layer LCL3 positioned in the emission area EMA of the third sub-pixel SPXL3. The first optical layer LCL1 may include the first color conversion layer CCL1 and the first color filter CF1 overlapping each other. The second optical layer LCL2 may include a second color conversion layer CCL2 and a second color filter CF2 overlapping each other. The third optical layer LCL3 may include a third color conversion layer CCL3 and a third color filter CF3 overlapping each other.

In one or more embodiments, a second bank BNK2 may be positioned in the non-emission area NEA of each of the first, second, and third sub-pixels SPXL1, SPXL2, and SPXL3.

The second bank BNK2 may be provided and/or formed on the first bank BNK1 in the non-emission area NEA of each of the first, second, and third sub-pixels SPXL1, SPXL2, and SPXL3. The second bank BNK2 may be a dam structure that surrounds the emission area EMA of each of the first, second, and third sub-pixels SPXL1, SPXL2, and SPXL3, and defines a position where each of the first, second, and third color conversion layers CCL1, CCL2, and CCL3 is to be supplied to finally define the emission area EMA. For example, the second bank BNK2 may be a dam structure that defines a position where the first color conversion layer CCL1 is to be supplied (or input) in the first sub-pixel SPXL1, a position where the second color conversion layer CCL2 is to be supplied (or input) in the second sub-pixel SPXL2, and a position where the third color conversion layer CCL3 is supplied (or input) in the third sub-pixel SPXL3, to finally set the emission area EMA of each of the first, second, and third sub-pixels SPXL1, SPXL2, and SPXL3.

The second bank BNK2 may include a light blocking material. For example, the second bank BNK2 may be a black matrix. According to one or more embodiments, the second bank BNK2 may be configured to include at least one light blocking material and/or reflective material to allow light emitted from the first, second, and third color conversion layers CCL1, CCL2, and CCL3 to further proceed in the image display direction (or the third direction DR3) of the display device, thereby improving light output efficiency of each of the first, second, and third color conversion layers CCL1, CCL2, and CCL3.

Each of the first, second, and third color conversion layers CCL1, CCL2, and CCL3 may be formed on (or at an upper portion of) the first electrode PE1, the first, second, third, and fourth intermediate electrodes CTE1, CTE2, CTE3, and CTE4, and the second electrode PE2 of each sub-pixel.

Each of the first, second, and third color conversion layers CCL1, CCL2, and CCL3 may include color conversion particles QD corresponding to a corresponding color. For example, each of the first, second, and third color conversion layers CCL1, CCL2, and CCL3 may include the color conversion particles QD that convert light of a first color emitted from the light-emitting elements LD1 to LD5 to into light of a second color (or a corresponding color) having a color different from the light of the first color.

When one sub-pixel among the first, second, and third sub-pixels SPXL1, SPXL2, and SPXL3 is a red pixel (or a red sub-pixel), the color conversion layer of the sub-pixel may include color conversion particles QD of a red quantum dot that converts the light of the first color emitted from the light-emitting elements LD1 to LD5 into the light of the second color, for example, red light.

When another sub-pixel among the first, second, and third sub-pixels SPXL1, SPXL2, and SPXL3 is a green pixel (or a green sub-pixel), the color conversion layer of the other sub-pixel may include color conversion particles QD of a green quantum dot that converts the light of the first color emitted from the light-emitting elements LD1 to LD5 into the light of the second color, for example, green light.

When a remaining sub-pixel among the first, second, and third sub-pixels SPXL1, SPXL2, and SPXL3 is a blue pixel (or a blue sub-pixel), the color conversion layer of the remaining sub-pixel may include color conversion particles QD of a blue quantum dot that converts the light of the first color emitted from the light-emitting elements LD1 to LD5 into the light of the second color, for example, blue light. For example, when the first sub-pixel SPXL1 is the blue pixel (or the blue sub-pixel), a light scattering layer including light scattering particles SCT may be provided instead of the first color conversion layer CCL1 including the color conversion particles QD. For example, when the light-emitting elements LD1 to LD5 emit blue-based light, the first sub-pixel SPXL1 may include the light scattering layer including the light scattering particles SCT. The above-described light scattering layer may be omitted according to one or more embodiments. According to one or more other embodiments, when the first sub-pixel SPXL1 is the blue pixel (or the blue sub-pixel), a transparent polymer may be provided instead of the first color conversion layer CCL1.

The first optical layer LCL1, the second optical layer LCL2, and the third optical layer LCL3 may have substantially similar or identical structures. Hereinafter, one or more embodiments is described based on the first optical layer LCL1 among the first, second, and third optical layers LCL1, LCL2, and LCL3.

A capping layer CPL may be located on the first color conversion layer CCL1 of the first optical layer LCL1 positioned in the emission area EMA and the second bank BNK2 positioned in the non-emission area NEA of the first sub-pixel SPXL1. The capping layer CPL may be completely (or entirely) provided in the display area DA (or the first sub-pixel area SPXA1) in which the first sub-pixel SPXL1 is positioned to cover the second bank BNK2 and the first color conversion layer CCL1. The capping layer CPL may be directly located on the second bank BNK2 and the first color conversion layer CCL1. The capping layer CPL may be an inorganic insulating layer including an inorganic material. The capping layer CPL may include at least one of silicon nitride (SiNₓ), silicon oxide (SiOₓ), silicon oxynitride (SiOₓN_{y}), and aluminum oxide (AlOₓ). The capping layer CPL may entirely cover the second bank BNK2 and the first color conversion layer CCL1 to reduce or prevent water, moisture, or the like from flowing into the display element layer DPL from the outside.

The capping layer CPL may have a flat surface while alleviating a step difference generated by components located thereunder. For example, the capping layer CPL may include an organic insulating layer including an organic material. The capping layer CPL may be a common layer commonly provided to the display area DA, but is not limited thereto.

In the one or more other embodiments corresponding to FIG. 16, a color filter layer CFL may be provided and/or formed on the capping layer CTL. The color filter layer CFL may include color filters CF1, CF2, and CF3 corresponding to respective colors of adjacent sub-pixels. For example, the color filter layer CFL may include a first color filter CF1 located on the first color conversion layer CCL1 of the first sub-pixel SPXL1, a second color filter CF2 located on the second conversion layer CCL2 of the second sub-pixel SPXL2, and a third color filter CF3 located on the third color conversion layer CCL3 of the third sub-pixel SPXL3. The first, second, and third color filters CF1, CF2, and CF3 may be located to overlap each other in the non-emission area NEA, and may be utilized as a light blocking member blocking light interference between adjacent sub-pixels. Each of the first, second, and third color filters CF1, CF2, and CF3 may include a color filter material that selectively transmits the light of the second color converted by a corresponding color conversion layer. For example, the first color filter CF1 may be a red color filter, the second color filter CF2 may be a green color filter, and the third color filter CF3 may be a blue color filter, but the disclosure is not limited thereto. The first color filter CF1 may be provided on one surface of the capping layer CPL to correspond to the first color conversion layer CCL1 in at least emission area EMA of the first sub-pixel SPXL1. The second color filter CF2 may be provided on one surface of the capping layer CPL to correspond to the second color conversion layer CCL2 in at least emission area EMA of the second sub-pixel SPXL2. The third color filter CF3 may be provided on one surface of the capping layer CPL to correspond to the third color conversion layer CCL3 in at least emission area EMA of the third sub-pixel SPXL3.

An encapsulation layer ENC may be provided and/or formed on the color filter layer CFL. The encapsulation layer ENC may include a fourth insulating layer INS4. The fourth insulating layer INS4 may be an inorganic insulating layer including an inorganic material or an organic insulating layer including an organic material. The fourth insulating layer INS4 may entirely cover components positioned thereunder, and may block water, moisture, or the like from flowing into the color filter layer CFL and the display element layer DPL from the outside.

In the first sub-pixel SPXL1 according to the above-described embodiments, the first color conversion layer CCL1 and the first color filter CF1 are located on the light-emitting elements LD1 to LD5 through a successive process. Therefore, light output efficiency may be improved by emitting light having excellent color reproducibility through the color conversion layer CCL1 and the first color filter CF1.

In one or more embodiments, the fourth insulating layer INS4 may be formed as multiple layers. For example, the fourth insulating layer INS4 may include at least two inorganic insulating layers and at least one organic insulating layer interposed between the two inorganic insulating layers. However, a configuration material and/or a structure of the fourth insulating layer INS4 may be variously changed. In addition, according to one or more embodiments, at least one overcoat layer, filler layer, an upper substrate, and/or the like may be further located on the fourth insulating layer INS4.

In the above-described embodiments, one or more embodiments in which the first color conversion layer CCL1 and the first color filter CF1 configuring the first optical layer LCL1 are formed in a successive process on the first electrode PE1, the first, second, third, and fourth intermediate electrodes CTE1, CTE2, CTE3, and CTE4, and the second electrode PE2 is described, but the disclosure is not limited thereto. According to one or more embodiments, as shown in FIG. 17, the upper substrate U_SUB including the first color filter CF1 may be located on the display element layer DPL including the first color conversion layer CCL1, and the display element layer DPL and the upper substrate U_SUB may be combined to each other through the intermediate layer CTL or the like.

The intermediate layer CTL may be a transparent adhesive layer (or an adhesive layer) for reinforcing adhesion force between the display element layer DPL including the first color conversion layer CCL1 and the upper substrate U_SUB including the first color filter CF1, for example, may be an optically clear adhesive layer, but is not limited thereto. According to one or more embodiments, the intermediate layer CTL may be a refractive index conversion layer for improving a light emission luminance of the first sub-pixel SPXL1 (or the pixel PXL) by converting a refractive index of light emitted from the light-emitting elements LD1, LD2, LD3, LD4, and LD5 and proceeding to the upper substrate U_SUB. According to one or more embodiments, the intermediate layer CTL may include a filler formed of an insulating material having an insulating property and an adhesive property.

In the one or more other embodiments corresponding to FIG. 17, the upper substrate U_SUB may configure an encapsulation substrate, a window member, an overcoat layer, and/or the like of the display device. The upper substrate U_SUB may include a base layer BSL (or a base substrate), the color filter layer CFL, and the capping layer CPL.

The base layer BSL may be a rigid substrate or a flexible substrate, and a material or a property thereof is not particularly limited. The base layer BSL may be formed of the same material as the substrate SUB or may be formed of a material different from that of the substrate SUB.

The color filter layer CFL may be located on one surface of the base layer BSL to face the display element layer DPL. The first color filter CF1 may be located on one surface of the base layer BSL to face the first color conversion layer CCL1.

The capping layer CPL may be located between the color filter layer CFL and the intermediate layer CTL. The capping layer CPL may be located on the color filter layer CFL to cover the color filter layer CFL, thereby protecting the color filter layer CFL. The capping layer CPL may be an inorganic layer including an inorganic material or an organic layer including an organic material.

In the above-described embodiments, one or more embodiments in which the first color conversion layer CCL1 and the first color filter CF1 configuring the first optical layer LCL1 are located on different substrates to face each other with the intermediate layer CTL interposed therebetween is described, but the disclosure is not limited thereto. According to one or more embodiments, as shown in FIG. 18, the first color conversion layer CCL1 and the first color filter CF1 may be formed in a successive process on a separate substrate, for example, the upper substrate U_SUB, and may be combined to the display element layer DPL including the first electrode PE1, the first, second, third, and fourth intermediate electrodes CTE1, CTE2, CTE3, and CTE4, and the second electrode PE2 through the intermediate electrode CTL or the like.

In the one or more other embodiments corresponding to FIG. 18, the upper substrate U_SUB may include the base layer BSL, the color filter layer CFL, a first capping layer CPL1, the second bank BNK2, the first color conversion layer CCL1, and a second capping layer CPL2.

The color filter layer CFL and the first color conversion layer CCL1 may be located on one surface of the base layer BSL to face the display element layer DPL. The first color filter CF1 of the color filter layer CFL may be provided on one surface of the base layer BSL to correspond to the first color conversion layer CCL1 in the emission area EMA. The first, second, and third color filters CF1, CF2, and CF3 of the color filter layer CFL may be located to overlap each other in the non-emission area NEA to be utilized as a light blocking member.

The first capping layer CPL1 may be located between the color filter layer CFL and the first color conversion layer CCL1. The first capping layer CPL1 may be positioned on the color filter layer CFL to cover the color filter layer CFL, thereby protecting the color filter layer CFL. The first capping layer CPL1 may be an inorganic layer including an inorganic material or an organic layer including an organic material.

The second bank BNK2 and the first color conversion layer CCL1 may be positioned on one surface of the first capping layer CPL1. The second bank BNK2 may be a dam structure that finally defines the emission area EMA of the first sub-pixel SPXL1. The second bank BNK2 may be a dam structure that finally defines the emission area EMA to which the first color conversion layer CCL1 is to be supplied in an operation of supplying the first color conversion layer CCL1.

The second capping layer CPL2 may be entirely located on the second bank BNK2 and the first color conversion layer CCL1. The second capping layer CPL2 may include at least one of silicon nitride (SiNₓ), silicon oxide (SiOₓ), silicon oxynitride (SiOₓN_{y}), and aluminum oxide (AlOₓ), but is not limited thereto. According to one or more embodiments, the second capping layer CPL2 may be configured of an organic layer including an organic material. The second capping layer CPL2 may be positioned on the first color conversion layer CCL1 to protect the first color conversion layer CCL1 from external water, moisture, and the like, thereby further improving reliability of the first color conversion layer CCL1.

The above-described upper substrate U_SUB may be combined to the display element layer DPL using the intermediate layer CTL.

Although the disclosure has been described with reference to the embodiments above, those skilled in the art or those having a common knowledge in the art will understand that the disclosure may be variously modified and changed without departing from the spirit and technical area of the disclosure described in the claims, which will be described later.

Therefore, the technical scope of the disclosure should not be limited to the contents described in the detailed description of the specification, but should be defined by the claims, with functional equivalents thereof to be included therein.

What is claimed is:

1. A pixel comprising:
a first sub-pixel, a second sub-pixel, and a third sub-pixel arranged in a first direction, and comprising:
an emission area; a non-emission area;
a first alignment electrode extending in the first direction;
a second alignment electrode extending in the first direction, and spaced apart from the first alignment electrode in a second direction crossing the first direction;
a light-emitting element between the first alignment electrode and the second alignment electrode, and comprising a first end and a second end opposite each other with respect to the second direction; and
a first electrode and a second electrode electrically connected to the light-emitting element, and spaced apart from each other in the second direction, the first electrode overlapping the first end of the light-emitting element, and the second electrode overlapping the second end of the light-emitting element.

2. The pixel according to claim 1, wherein the first electrode of each of the first, second, and third sub-pixels is spaced apart from the first electrode of one of the sub-pixels adjacent in the first direction, and
wherein the second electrode of each of the first, second, and third sub-pixels is connected to the second electrode of the one of the sub-pixels adjacent in the first direction.

3. The pixel according to claim 2, wherein the second electrode of the first sub-pixel, the second electrode of the second sub-pixel, and the second electrode of the third sub-pixel are integrally provided.

4. The pixel according to claim 2, further comprising:
a first bank in the non-emission area, and defining a first opening corresponding to the emission area, and a second opening spaced apart from the first opening;
a first connection line extending in the second direction in the non-emission area of the first sub-pixel, and connected to the first alignment electrode; and
a second connection line extending in the second direction in the non-emission area of the third sub-pixel, and connected to the second alignment electrode.

5. The pixel according to claim 4, wherein the first alignment electrode of the first sub-pixel, the first alignment electrode of the second sub-pixel, and the first alignment electrode of the third sub-pixel are connected to each other, and
wherein the second alignment electrode of the first sub-pixel, the second alignment electrode of the second sub-pixel, and the second alignment electrode of the third sub-pixel are connected to each other.

6. The pixel according to claim 5, further comprising:
a first bridge pattern in the non-emission area of the first sub-pixel, and electrically connected to the second electrode of the first sub-pixel;
a second bridge pattern in the non-emission area of the second sub-pixel, and electrically connected to the second electrode of the second sub-pixel; and
a third bridge pattern in the non-emission area of the third sub-pixel, and electrically connected to the second electrode of the third sub-pixel,
wherein the first bridge pattern, the second bridge pattern, and the third bridge pattern are spaced apart from each other.

7. The pixel according to claim 6, wherein the third bridge pattern and the second connection line are integrally provided.

8. The pixel according to claim 7, wherein the first alignment electrode, the second alignment electrode, the first bridge pattern, the second bridge pattern, the third bridge pattern, the first connection line, and the second connection line are in a same layer, and comprise a same material.

9. The pixel according to claim 8, further comprising:
a substrate;
a storage capacitor above the substrate, and electrically connected to the first end of the light-emitting element;
a transistor above the substrate, and electrically connected to the storage capacitor;
a data line above the substrate, configured to be electrically connected to the transistor, configured to receive a data signal, and extending in a direction perpendicular to an extension direction of the first and second alignment electrodes;
a first power line above the substrate, configured to be electrically connected to the transistor, and configured to receive a voltage of first driving power;
a second power line above the substrate, configured to be electrically connected to the second end of the light-emitting element, and configured to receive a voltage of second driving power; and
a passivation layer above the transistor, the first power line, and the second power line, and exposing a portion of the storage capacitor, a portion of the first power line, and a portion of the second power line.

10. The pixel according to claim 9, wherein the second power line exposed in the first sub-pixel is electrically connected to the first bridge pattern,
wherein the second power line exposed in the second sub-pixel is electrically connected to the second bridge pattern, and
wherein the second power line exposed in the third sub-pixel is electrically connected to the third bridge pattern.

11. The pixel according to claim 6, wherein the first alignment electrode comprises a (1-1)-th alignment electrode, a (1-2)-th alignment electrode, a (1-3)-th alignment electrode, a (1-4)-th alignment electrode, and (1-5)-th alignment electrode extending in the first direction, and spaced apart in the second direction,
wherein the second alignment electrode comprises a (2-1)-th alignment electrode, a (2-2)-th alignment electrode, a (2-3)-th alignment electrode, a (2-4)-th alignment electrode, and a (2-5)-th alignment electrode extending in the first direction, and spaced apart in the second direction, and
wherein the first alignment electrode and the second alignment electrode are alternately located along the second direction.

12. The pixel according to claim 11, wherein the first electrode overlaps the (2-1)-th alignment electrode, and wherein the second electrode overlaps the (1-5)-th alignment electrode.

13. The pixel according to claim 12, further comprising:
a first intermediate electrode between the first electrode and the second electrode, spaced apart from the first and second electrodes in the second direction, and overlapping the (1-1)-th alignment electrode and the (2-2)-th alignment electrode;
a second intermediate electrode between the first intermediate electrode and the second electrode, spaced apart from the first intermediate electrode and the second electrode in the second direction, and overlapping the (1-2)-th alignment electrode and the (2-3)-th alignment electrode;
a third intermediate electrode between the second intermediate electrode and the second electrode, spaced apart from the second intermediate electrode and the second electrode in the second direction, and overlapping the (1-3)-th first alignment electrode and the (2-4)-th second alignment electrode; and
a fourth intermediate electrode between the third intermediate electrode and the second electrode, spaced apart from the third intermediate electrode and the second electrode in the second direction, and overlapping the (1-4)-th alignment electrode and the (2-5)-th alignment electrode.

14. The pixel according to claim 13, wherein, in the emission area, the first electrode, the first intermediate electrode, the second intermediate electrode, the third intermediate electrode, the fourth intermediate electrode, and the second electrode are sequentially arranged along the second direction based on the first electrode of a corresponding sub-pixel.

15. The pixel according to claim 14, wherein the first electrode, the second intermediate electrode, and the fourth intermediate electrode are in a same layer, and comprise a same material, and
wherein the second electrode, the first intermediate electrode, and the third intermediate electrode are in a same layer, and comprise a same material.

16. The pixel according to claim 14, wherein the first electrode, the first intermediate electrode, the second intermediate electrode, the third intermediate electrode, the fourth intermediate electrode, and the second electrode are in a same layer, and comprise a same material.

17. The pixel according to claim 14, further comprising:
a first light-emitting element between the (2-1)-th alignment electrode and the (1-1)-th alignment electrode, and comprising a first end electrically connected to the first electrode, and a second end electrically connected to the first intermediate electrode;
a second light-emitting element between the (2-2)-th alignment electrode and the (1-2)-th alignment electrode, and comprising a first end electrically connected to the first intermediate electrode, and a second end electrically connected to the second intermediate electrode;
a third light-emitting element between the (2-3)-th alignment electrode and the (1-3)-th alignment electrode, and comprising a first end electrically connected to the second intermediate electrode, and a second end electrically connected to the third intermediate electrode;
a fourth light-emitting element between the (2-4)-th alignment electrode and the (1-4)-th alignment electrode, and comprising a first end electrically connected to the third intermediate electrode, and a second end electrically connected to the fourth intermediate electrode; and
a fifth light-emitting element between the (2-5)-th alignment electrode and the (1-5)-th alignment electrode, and comprising a first end electrically connected to the fourth intermediate electrode, and a second end electrically connected to the second electrode.

18. The pixel according to claim 17, wherein the first to fifth light-emitting elements comprise a first semiconductor layer, an active layer, and a second semiconductor layer,
wherein the first semiconductor layer comprises an n-type semiconductor layer doped with an n-type dopant,
wherein the second semiconductor layer comprises a p-type semiconductor layer doped with a p-type dopant,
wherein the second semiconductor layer of the first to fifth light-emitting elements is at the first end of a corresponding light-emitting element, and
wherein the first semiconductor layer of the first to fifth light-emitting elements is at the second end of the corresponding light-emitting element.

19. The pixel according to claim 17, further comprising:
a second bank above the first bank in the non-emission area;
a color conversion layer above the first to fifth light-emitting elements in the emission area, and configured to convert light of a first color emitted from the first to fifth light-emitting elements into light of a second color; and
a color filter above the color conversion layer, and configured to selectively transmit the light of the second color.

20. A display device comprising:
a substrate comprising a display area and a non-display area; and
one or more pixels in the display area, comprising an emission area and a non-emission area, and comprising first, second, and third sub-pixels arranged along a first direction,
wherein the first, second, and third sub-pixels comprise:
a pixel circuit layer above the substrate, and comprising at least one transistor; and
a display element layer above the pixel circuit layer, and comprising:
a first alignment electrode extending in the first direction;
a second alignment electrode extending in the first direction, and spaced apart from the first alignment electrode in a second direction crossing the first direction;
a light-emitting element between the first alignment electrode and the second alignment electrode, comprising a first end and a second end opposite each other with respect to the second direction, and configured to be electrically connected to the transistor; and
a first electrode and a second electrode electrically connected to the light-emitting element, and spaced apart from each other in the second direction, the first electrode overlapping, and electrically connected to, the first end of the light-emitting element, and the second electrode overlapping, and electrically connected to, the second end of the light-emitting element.
